(19) United States
(12) Patent Application Publication
(10) Pub. No.: US 2023/0291372 A1
(43) Pub. Date: Sep. 14, 2023

(54) AMPLIFIER CIRCUIT WITH VARIABLE TEMPERATURE COEFFICIENT OF GAIN, AND CIRCUIT FOR GENERATING VOLTAGE WITH VARIABLE TEMPERATURE COEFFICIENT, WHICH BECOMES REFERENCE POTENTIAL AT REFERENCE TEMPERATURE, DIRECT VOLTAGE GENERATING CIRCUIT, AND CIRCUIT FOR COMPENSATING FOR TEMPERATURE DRIFT OF ANOTHER AMPLIFIER CIRCUIT, WHICH USE THE AMPLIFIER CIRCUIT

(71) Applicant: NF HOLDINGS CORPORATION, Kanagawa (JP)

(72) Inventors: Shingo SOBUKAWA, Kanagawa (JP); Takehito KAMIMURA, Kanagawa (JP); Tatsuru TAMORI, Tokyo (JP)

(21) Appl. No.: 18/179,381

(22) Filed: Mar. 7, 2023

(30) Foreign Application Priority Data
Mar. 9, 2022 (JP) 2022-036017

(51) Int. Cl. H03F 3/45; H03G 3/00; H03F 1/32; H03F 1/30

(52) U.S. Cl. CPC H03F 3/45475; H03G 3/001; H03F 1/3211; H03F 1/301

(57) ABSTRACT

An amplifier circuit 1001 with a variable temperature coefficient of a gain is an amplifier circuit with a variable temperature coefficient of a gain in which a variable resistor VR is connected between a first signal and a second signal having temperature coefficients of an amplification factor different from each other, a variable output of the variable resistor VR is connected to an input of a buffer amplifier Ub, and an output of the buffer amplifier Ub is used as an output Vo, wherein the first signal is an output of a first temperature coefficient circuit 100, and the second signal is an output of another amplifier circuit 501.

The contents of the following Japanese patent application(s) are incorporated herein by reference:
NO. 2022-036017 filed on Mar. 9, 2022.

### BACKGROUND

### 1. Technical Field

The present invention relates to an application circuit such as an amplifier circuit with a variable temperature coefficient of a gain, and a circuit for generating a voltage with a variable temperature coefficient, which becomes a reference potential at a reference temperature, a direct voltage generating circuit, and a circuit for compensating for a temperature drift of another amplifier circuit, which use the amplifier circuit.

### 2. Related Art

Conventionally, an amplifier circuit using an operational amplifier (OP Amp) is suggested in which a temperature coefficient of a gain (Vo/Vi) is set to a predetermined value by using a temperature coefficient resistor as a part of a feedback resistor or input resistor (for example, Patent Document 1).

In this case, when a temperature coefficient of a usual resistor is sufficiently smaller than a temperature coefficient of the temperature coefficient resistor, the temperature coefficient of a gain becomes [(resistance value of temperature coefficient resistor)/{(resistance value of usual resistor)+(resistance value of temperature coefficient resistor)}] times of the temperature coefficient of the temperature coefficient resistor and becomes smaller.

### PRIOR ART DOCUMENT

### Patent Document

Patent Document 1: Japanese Unexamined Patent Application, Publication No. H09-072755

### SUMMARY OF INVENTION

### Technical Problem

In the amplifier circuit of Patent Document 1, when the temperature coefficient resistor is used as a part of the feedback resistor, a temperature coefficient of an absolute value of a gain becomes the same direction as the temperature coefficient of the temperature coefficient resistor, and when the temperature coefficient resistor is used as a part of the input resistor, the temperature coefficient of the absolute value of the gain becomes an opposite direction to the temperature coefficient of the temperature coefficient resistor. Therefore, there is no choice but to select either positive or negative temperature coefficient of the gain, depending on the place where the temperature coefficient resistor is used.

In this way, the temperature coefficient of the gain and its positive and negative are uniquely determined by the resistance value of each resistor and the temperature coefficient of the temperature coefficient resistor, and cannot be varied to an arbitrary temperature coefficient. For this reason, when compensating for a temperature coefficient of another target object, it is difficult to address variations in temperature coefficient of the target object or changes over time.

The present invention has been made in view of the above situations, and provides an amplifier circuit with a variable temperature coefficient of a gain, which enables a temperature coefficient of a gain to continuously vary to an arbitrary positive or negative value, and a circuit for generating a voltage with a variable temperature coefficient, which becomes a reference potential at a reference temperature, a direct voltage generating circuit, and a circuit for compensating for a temperature drift of another amplifier circuit, which use the amplifier circuit.

### SUMMARY

In order to address such a problem, the present invention provides an amplifier circuit with a variable temperature coefficient of a gain in which a variable resistor is connected between a first signal and a second signal having temperature coefficients of an amplification factor different from each other, a variable output of the variable resistor is connected to an input of a buffer amplifier, and an output of the buffer amplifier is used as an output, wherein the first signal is an output of a first temperature coefficient circuit, and the second signal is an output of another amplifier circuit, an output of a second temperature coefficient circuit, an output of a temperature coefficient inverting circuit configured to use the first signal as an input, or an input of the amplifier circuit with a variable temperature coefficient of a gain.

In the amplifier circuit with a variable temperature coefficient of a gain, when an impedance of a load connected to an output of the amplifier circuit with the variable temperature coefficient of a gain is higher than an impedance of the variable resistor seen from the variable output, the buffer amplifier may be omitted.

In the amplifier circuit with a variable temperature coefficient of a gain, a voltage-current converting circuit may be used as the buffer amplifier, and a current output may be used.

In the amplifier circuit with a variable temperature coefficient of a gain, the first temperature coefficient circuit and the second temperature coefficient circuit may be each an inverting amplifier circuit in which a temperature coefficient resistor is used for one or more of a feedback resistor or a gain resistor, a non-inverting amplifier circuit in which a temperature coefficient resistor is used for one or more of a feedback resistor or a gain resistor, a non-inverting amplifier circuit in which a first attenuator is provided to an input and a temperature coefficient resistor is used for one or more of a resistor configuring the first attenuator, a feedback resistor or a gain resistor, a non-inverting amplifier circuit in which a second attenuator is provided to an output and a temperature coefficient resistor is used for one or more of a resistor configuring the second attenuator, a feedback resistor or a gain resistor, or a non-inverting amplifier circuit in which a third attenuator is provided to an output, a temperature coefficient resistor is used for one or more of a resistor configuring the third attenuator, a feedback resistor or a gain resistor, and a buffer amplifier is provided to an output of the third attenuator.

In the amplifier circuit with a variable temperature coefficient of a gain, in the temperature coefficient inverting circuit, a non-inverting input of an operational amplifier configuring the temperature coefficient inverting circuit may be connected to an input of the amplifier circuit with a variable temperature coefficient of a gain, or an output of another amplifier circuit, an inverting input of the operational amplifier configuring the temperature coefficient inverting circuit may be connected to one end of a feedback resistor and one end of a gain resistor, an output of the operational amplifier configuring the temperature coefficient inverting circuit may be connected to an opposite end of the feedback resistor, an output of the first temperature coefficient circuit may be connected to an opposite end of the gain resistor, and the feedback resistor and the gain resistor may have substantially the same resistance values.

In the amplifier circuit with a variable temperature coefficient of a gain, a temperature coefficient of another amplifier circuit having a temperature coefficient in an output may be compensated.

In the amplifier circuit with a variable temperature coefficient of a gain, the temperature coefficients of an amplification factor may be adjusted to temperature coefficients proportional to an absolute temperature.

In the amplifier circuit with a variable temperature coefficient of a gain, a direct voltage source having a temperature coefficient in an output voltage may be connected to the input, and the temperature coefficient of the direct voltage source may be compensated and output.

In the amplifier circuit with a variable temperature coefficient of a gain, a direct voltage source having a temperature coefficient in an output voltage may be connected to the input, a first variable resistor and a second variable resistor may be provided as the variable resistor, the buffer amplifier may not be provided, a variable output of the first variable resistor may be connected to a non-inverting input of a first operational amplifier, a variable output of the second variable resistor may be connected to a non-inverting input of a second operational amplifier, an output of the first operational amplifier may be connected to an inverting input of the first operational amplifier via a first diode, an output of the second operational amplifier may be connected to an inverting input of the second operational amplifier via a second diode, the inverting input of the first operational amplifier and the inverting input of the second operational amplifier may be connected in common, a constant current source or a resistor may be provided between the common connection and a voltage source, and the common connection may be used as an output, so that the temperature coefficient of the direct voltage source may be independently compensated and output at temperatures higher and lower than a reference temperature.

In the amplifier circuit with a variable temperature coefficient of a gain, the whole or a part of the amplifier circuit with a variable temperature coefficient of a gain may be configured as a circuit module.

In the amplifier circuit with a variable temperature coefficient of a gain, a range of the temperature coefficient may be switchable.

The present invention also provides a circuit for generating a voltage with a variable temperature coefficient, which becomes a reference potential at a reference temperature, by using the amplifier circuit with a variable temperature coefficient of a gain in which the second signal is set to an output of the temperature coefficient inverting circuit, a third signal is set to a signal in which a polarity of the output of the temperature coefficient inverting circuit is inverted, or a reference potential, and the variable resistor is connected between the second signal and the third signal, which have temperature coefficients of an amplification factor different from each other, and by applying a direct voltage to the input of the amplifier circuit with a variable temperature coefficient of a gain.

The present invention also provides a direct voltage generating circuit using the amplifier circuit with a variable temperature coefficient of a gain, the direct voltage generating circuit being configured to output a voltage proportional to an absolute temperature by connecting a direct voltage source to an input.

The present invention also provides a circuit using the circuit for generating a voltage with a variable temperature coefficient, which becomes a reference potential at a reference temperature, and is configured to apply an output of the circuit for generating a voltage with a variable temperature coefficient to an input of another amplifier circuit, and to compensate for a temperature drift of the other amplifier circuit.

### Effect of the Invention

According to the amplifier circuit with a variable temperature coefficient of a gain, and the circuit for generating a voltage with a variable temperature coefficient, which becomes a reference potential at a reference temperature, the direct voltage generating circuit, and the circuit for compensating for a temperature drift of another amplifier circuit, which use the amplifier circuit of the present invention, the temperature coefficient can be significantly improved in a circuit in which the temperature coefficient is problematic.

### BRIEF DESCRIPTION OF THE DRAWINGS

FIG. 1 is a diagram showing an example of a basic configuration of a temperature coefficient circuit.

FIG. 2A is a diagram showing an example of a configuration of a temperature coefficient resistor.

FIG. 2B is a diagram showing an example of the configuration of the temperature coefficient resistor.

FIG. 2C is a diagram showing an example of the configuration of the temperature coefficient resistor.

FIG. 3 is a diagram showing another example of the basic configuration of the temperature coefficient circuit.

FIG. 4 is a diagram showing another example of the basic configuration of the temperature coefficient circuit.

FIG. 5 is a diagram showing another example of the basic configuration of the temperature coefficient circuit.

FIG. 6A is a diagram showing an example of a variation of a variable resistor.

FIG. 6B is a diagram showing an example of a variation of the variable resistor.

FIG. 6C is a diagram showing an example of a variation of the variable resistor.

FIG. 6D is a diagram showing an example of a variation of the variable resistor.

FIG. 6E is a diagram showing an example of a variation of the variable resistor.

FIG. 7 is a diagram showing an example of a configuration of an amplifier circuit (inverting amplifier circuit, one direction) with a variable temperature coefficient of a gain in an embodiment of the circuit of the present invention.

FIG. 8 is a diagram showing another example of the configuration of the amplifier circuit (inverting amplifier circuit, one direction) with a variable temperature coefficient of a gain.

FIG. 9 is a diagram showing temperature dependence of a gain G when R2 is set as a temperature coefficient resistor in the circuit in FIG. 8.

FIG. 10 is a diagram showing an example of the configuration of the amplifier circuit (non-inverting amplifier circuit, one direction) with a variable temperature coefficient of a gain.

FIG. 11 is a diagram showing an example of the configuration of the amplifier circuit (non-inverting amplifier circuit with a gain G=1, one direction) with a variable temperature coefficient of a gain.

FIG. 12 is a diagram showing another example of the configuration of the amplifier circuit (non-inverting amplifier circuit with a gain G=1, one direction) with a variable temperature coefficient of a gain.

FIG. 13 is a diagram showing an example of the configuration of the amplifier circuit (non-inverting amplifier circuit with a gain G=1, two directions) with a variable temperature coefficient of a gain.

FIG. 14 is a diagram showing the temperature dependence of the gain G when R4 is set as the temperature coefficient resistor in the circuit in FIG. 13.

FIG. 15 is a diagram showing an example of the configuration of the amplifier circuit (non-inverting amplifier circuit with the gain G>1, two directions) with a variable temperature coefficient of a gain.

FIG. 16 is a diagram showing another example of the configuration of the amplifier circuit (non-inverting amplifier circuit with the gain G>1, two directions) with a variable temperature coefficient of a gain.

FIG. 17 is a diagram showing an example of the configuration of the amplifier circuit (inverting amplifier circuit with the gain G<0, two directions) with a variable temperature coefficient of a gain.

FIG. 18 is a diagram showing another example of the configuration of the amplifier circuit (inverting amplifier circuit with the gain G<0, two directions) with a variable temperature coefficient of a gain.

FIG. 19 shows an example of a resistance value and a temperature coefficient in an amplifier circuit 1005.

FIG. 20 is a modified circuit of the amplifier circuit 1005, showing an example of a configuration using a 1/50 attenuator.

FIG. 21 is a modified circuit of an amplifier circuit 1012, showing an example of a range switching circuit of a temperature coefficient of an amplification factor, in which a switchable attenuator is used.

FIG. 22 is a diagram showing an example of a configuration of a temperature characteristic compensation circuit of an IV amplifier.

FIG. 23 is a diagram showing an example of a configuration of an amplifier circuit in which an amplification factor is proportional to an absolute temperature.

FIG. 24 shows a temperature characteristic of a reference voltage built into TL431 (Texas Instruments Incorporated), which is a direct voltage source IC commonly used by one skilled in the art.

FIG. 25 is a diagram showing an example of a configuration of a circuit configured to compensate for a temperature characteristic of a direct voltage source by using a circuit similar to an amplifier circuit 1006.

FIG. 26 is a diagram showing an example of a configuration of a circuit configured to perform V-shaped compensation on the temperature characteristic of the direct voltage source.

FIG. 27 is a diagram showing an example of a configuration of a circuit configured to perform inverted V-shaped compensation on the temperature characteristic of the direct voltage source.

FIG. 28 is a diagram showing the temperature dependence of the gain G when a temperature coefficient resistor having a positive temperature coefficient is used as R4, a slider of a variable resistor VR_{A} is set close to Vo1, and a slider of a variable resistor VR_{B} is set close to Vo2 in the circuit in FIG. 26.

FIG. 29 is a diagram showing an example of a configuration of a circuit configured to perform a temperature coefficient output of 0 V at a reference temperature.

FIG. 30 is a diagram showing the temperature dependence of the gain G when R4 is set as the temperature coefficient resistor in the circuit in FIG. 29.

FIG. 31 is a diagram showing an example of a configuration in which a gain of a buffer amplifier Ub is 10 times.

FIG. 32 is a diagram showing an example of a configuration of a circuit configured to perform temperature drift compensation of a high-speed OP amplifier using a temperature coefficient output of 0 V at a reference temperature.

FIG. 33 is a diagram showing another example of the configuration of the circuit configured to perform temperature drift compensation of a high-speed OP amplifier using a temperature coefficient output of 0 V at a reference temperature.

### DESCRIPTION OF EXEMPLARY EMBODIMENTS

Hereinafter, embodiments of the present invention will be described with reference to the drawings. However, the present invention is not limited to the following description. Various modifications and changes can be made by one skilled in the art based on the gist of the invention described in claims or disclosed in a detailed description of the embodiments. Such modifications and changes also fall within the scope of the present invention.

Here, it is assumed in an inverting amplifier circuit that a gain resistor is denoted as R1 and a feedback resistor is denoted as R2 in a temperature coefficient circuit 100 and the gain resistor is denoted as R1″ and the feedback resistor is denoted as R2″ in a temperature coefficient circuit 100′ and another amplifier circuit 501. It is assumed in a non-inverting amplifier circuit that the gain resistor is denoted as R3 and the feedback resistor is denoted as R4 in temperature coefficient circuits 200, 300, and 400 and the gain resistor is denoted as R3″ and the feedback resistor is denoted as R4″ in a temperature coefficient circuit 200′ and another amplifier circuit 502. It is assumed that an operational amplifier of a temperature coefficient circuit 100, 100′, 200, 200′, 300, 400 is denoted as U and an operational amplifier of another amplifier circuit 501, 502 is denoted as U″. It is assumed that a gain resistor is denoted as R5, a feedback resistor is denoted as R6, and an operational amplifier is denoted as U′ in a temperature coefficient inverting circuit 503. In the case of the temperature coefficient inverting circuit 503 given that R5 is the same as R6 (R5=R6), it is preferable to use a pair of resistors whose relative resistance values or relative temperature coefficients are small, as R5 and R6. It is assumed that a gain resistor is denoted as R7, a feedback resistor is denoted as R8, and an operational amplifier is denoted as U_{INV} in an inverting amplifier circuit 504.

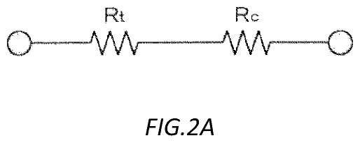

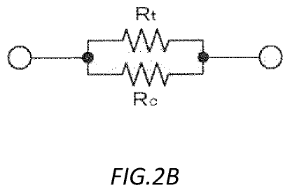

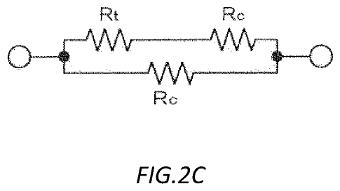

Operational amplifiers except U_{IV} and U_{HF} make a formula simple and clear on the premise of an ideal OP amplifier. The temperature coefficient resistor mainly assumes a linear temperature coefficient resistor, but includes a case in which a resistor or the like having a temperature coefficient different from that of another resistor is intentionally used and cases in FIGS. 2A to 2C. Any one or more of the resistors R1 to R4 and R1′ to R4′ are set as temperature coefficient resistors. It is assumed that a temperature coefficient of the temperature coefficient resistor is sufficiently larger than that of another resistor, and is linear. It is assumed that an input voltage signal is denoted as Vi, an output voltage signal is denoted as Vo, and a gain G=Vo/Vi. Hereafter, the gain G is sometimes referred to as an amplification factor.

Ub and Ub′ are buffer amplifiers, and ‘gain=1’ is assumed unless otherwise specified. Note that, if necessary, Ub and Ub′ may be used as a voltage-current converting circuit to output current, and in this case, the voltage output signal Vo is replaced with a current output signal Io. When an impedance of a load connected to Vo is sufficiently higher than an impedance seen from a variable output of a variable resistor, the buffer amplifier Ub may be omitted.

It is also preferable to use, as a circuit module, the whole or a part of an amplifier circuit with a variable temperature coefficient of a gain or application circuits thereof for a reduction in size and weight or facilitation of addition to another circuit.

(Basic Circuit (Inverting Amplifier Circuit) of Temperature Coefficient Circuit)

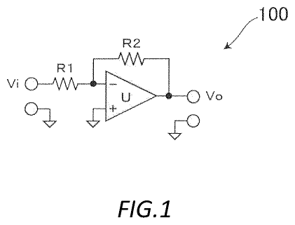

FIG. 1 shows an example of a configuration of an inverting amplifier circuit as a basic circuit of the temperature coefficient circuit 100. The gain G of the circuit 100 is represented by the formula 1. When R1≠∞ and R2≠0, the gain is smaller than zero (G<0). That is, in the circuit 100, ‘0<gain G’ is not realized. For example, when R2 is set as the temperature coefficient resistor, a temperature coefficient of an absolute value of the gain G becomes the same as the temperature coefficient of the temperature coefficient resistor. The temperature coefficient circuit 100 in FIG. 1 is an inverting amplifier circuit in which a temperature coefficient resistor is used for one or more of the feedback resistors or the gain resistors.

$$G = - \frac{R 2}{R 1} \qquad ( Formula 1 )$$

In the temperature coefficient circuit 100 in FIG. 1, for each case where the temperature coefficient resistor is set to R1 or R2, directions of the temperature coefficients of the temperature coefficient resistor and the temperature coefficients of the absolute value of the amplification factor, and a relationship between the temperature coefficients of the temperature coefficient resistor and the temperature coefficients of the absolute value of the amplification factor are shown in Table 1. When the temperature coefficient resistor is set to R1, the directions of the temperature coefficients of the temperature coefficient resistor and the temperature coefficients of the absolute value of the amplification factor are the opposite directions, and the relationship between the temperature coefficients of the temperature coefficient resistor and the temperature coefficients of the absolute value of the amplification factor is a non-linear relationship (inversely proportional). When the temperature coefficient resistor is set to R2, the directions of the temperature coefficients of the temperature coefficient resistor and the temperature coefficients of the absolute value of the amplification factor are the same directions, and the relationship between the temperature coefficients of the temperature coefficient resistor and the temperature coefficients of the absolute value of the amplification factor is a linear relationship (proportional).

TABLE 1

| | | Relationship Between |
|---|---|---|
| | Directions of Temperature | Temperature |
| | Coefficients of Temperature | Coefficients of Temperature |
| Position of | Coefficient Resistor and | Coefficient Resistor and |
| Temperature | Temperature Coefficients | Temperature |
| Coefficient | of Absolute Value of | Coefficients of Absolute |
| Resistor | Amplification Factor | Value of Amplification Factor |
| R1 | Opposite Directions | Non-linear relationship |
| | | (inversely proportional) |
| R2 | Same Directions | Linear relationship |
| | | (proportional) |

For example, when the temperature coefficient resistor is used for R1 in the temperature coefficient circuit 100 in FIG. 1, the gain G and the resistance value of the temperature coefficient resistor have an inversely proportional relationship. For this reason, the temperature coefficient of the absolute value of the gain G also has an inversely proportional relationship with the temperature coefficient of the temperature coefficient resistor. Therefore, when the temperature is set to a horizontal axis and the gain G is set to a vertical axis, the relationship therebetween becomes a non-linear relationship.

However, as an example, even when a temperature coefficient resistor having a large temperature coefficient of 4000 ppm/° C. is used and an ambient temperature largely changes up to 0 to 50° C., the inversely proportional relationship is close to a straight-line relationship, and the curvilinearity can be ignored in many cases. In this case, when the temperature is set to the horizontal axis and the gain G is set to the vertical axis, the relationship therebetween may be regarded as a substantially linear relationship.

On the other hand, a temperature coefficient of a temperature coefficient compensation target connected to Vi, and temperature coefficients of a temperature coefficient resistor and a usual resistor used in a temperature coefficient compensation circuit also may not have a perfect temperature coefficient linearity. In order to more completely compensate for a temperature coefficient to be finally obtained, the temperature coefficient resistor may be intentionally used at a location where the temperature coefficient becomes curved (non-linear) in the opposite direction.

(Temperature Coefficient Resistor)

In the above, the example in which R1 or R2 is used as the temperature coefficient resistor and some resistors are used as temperature resistors as they are is shown. However, examples in which the temperature coefficient resistor is used as a part of the resistors (FIG. 2A), a plurality of resistors are used as the temperature coefficient resistor (FIG. 2B), and a combination in FIGS. 2A and 2B is used (FIG. 2C), etc. are also possible, and these examples are also included. In FIG. 2A, a temperature coefficient resistor Rt and a usual resistor Rc are connected in series. In FIG. 2B, the temperature coefficient resistor Rt and the usual resistor Rc are connected in parallel. In FIG. 2C, the temperature coefficient resistor Rt and the usual resistor Rc are connected in series, to which a usual resistor Rc is connected in parallel. Overall temperature coefficients are all smaller than the temperature coefficients of the temperature coefficient resistors in use. FIGS. 2A to 2C can be applied to the temperature coefficient resistor of all circuits of the present invention. Note that, Patent Document 1 corresponds to a case in which a part of the resistors R1 or R2 in the circuit in FIG. 1 is used as the temperature coefficient resistor in FIG. 2A.

(Basic Circuit (Non-inverting Amplifier Circuit) of Temperature Coefficient Circuit)

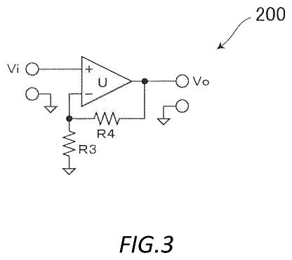

FIG. 3 shows an example of a configuration of a non-inverting amplifier circuit as a basic circuit of a temperature coefficient circuit 200. The gain G of the circuit 200 is represented by the formula 2. When R3≠∞ and R4≠0, the gain is greater than 1 (G>1). That is, in the circuit 200, ‘gain G<1’ is not realized. For example, when R4 is set as the temperature coefficient resistor, the temperature coefficient of the gain G is R3·(R3+R4) times of the temperature coefficient resistor. The temperature coefficient circuit 200 in FIG. 3 is a non-inverting amplifier circuit in which a temperature coefficient resistor is used for one or more of the feedback resistors or the gain resistors.

$$G = 1 + \frac{R 4}{R 3} \qquad ( Formula 2 )$$

In the temperature coefficient circuit 200 in FIG. 3, for each case where the temperature coefficient resistor is set to R3 or R4, directions of the temperature coefficients of the temperature coefficient resistor and the amplification factor, and a relationship between the temperature coefficients of the temperature coefficient resistor and the amplification factor are shown in Table 2. When the temperature coefficient resistor is set to R3, the directions of the temperature coefficients of the temperature coefficient resistor and the amplification factor are the opposite directions, and the relationship between the temperature coefficients of the temperature coefficient resistor and the amplification factor is a non-linear relationship. When the temperature coefficient resistor is set to R4, the directions of the temperature coefficients of the temperature coefficient resistor and the amplification factor are the same directions, and the relationship between the temperature coefficients of the temperature coefficient resistor and the amplification factor is a linear relationship.

| | Directions of Temperature | Relationship Between |
|---|---|---|
| | Coefficients of | Temperature Coefficients |
| Position of | Temperature | of Temperature |
| Temperature | Coefficient Resistor and | Coefficient Resistor |
| Coefficient | Temperature Coefficients | and Temperature Coefficients |
| Resistor | of Amplification Factor | of Amplification Factor |
| R3 | Opposite Directions | Non-linear relationship |
| R4 | Same Directions | Linear relationship |

(Temperature Coefficient Circuit (Non-Inverting Amplifier Circuit in which 0<Gain G≤1 is Also Possible))

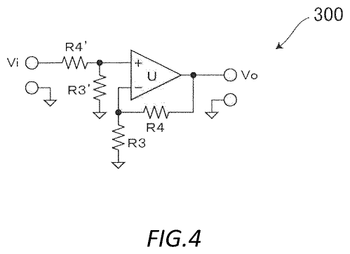

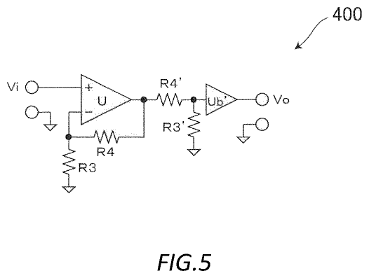

FIGS. 4 and 5 are temperature coefficient circuits 300 and 400, showing examples of a configuration of implementing a non-inverting amplifier by one operational amplifier, in which a gain of 0<gain G≤1, which is not realized in the circuits in FIGS. 1 and 2A to 2C, is achieved. It is assumed that resistors of divider circuits (attenuators) in the temperature coefficient circuits 300 and 400 in FIGS. 4 and 5 are R3′ and R4′.

In FIG. 4, in the temperature coefficient circuit 200 in FIG. 3, the resistor R4′ is connected between the input signal Vi and a non-inverting input of the operational amplifier U, one end of the resistor R3′ is connected between the resistor R4′ and the non-inverting input of the operational amplifier U, and an opposite end of the resistor R3′ is grounded. The temperature coefficient circuit 300 in FIG. 4 is a non-inverting amplifier circuit in which an attenuator configured by the resistors R3′ and R4′ is provided at an input and a temperature coefficient resistor is used for one or more of the resistors configuring the attenuator, the feedback resistor, or the gain resistor.

In FIG. 5, in the temperature coefficient circuit 200 in FIG. 3, a buffer amplifier Ub′ is provided, the resistor R4′ is connected between an output terminal of the operational amplifier U and an input of the buffer amplifier Ub′, one end of the resistor R3′ is connected between the resistor R4′ and the input of the buffer amplifier Ub′, and the opposite end of the resistor R3′ is grounded. The temperature coefficient circuit 400 in FIG. 5 is a non-inverting amplifier circuit in which an attenuator configured by the resistors R3′ and R4′ is provided at an output and a temperature coefficient resistor is used for one or more of the resistors configuring the attenuator, the feedback resistor, or the gain resistor, or a non-inverting amplifier circuit in which the buffer amplifier Ub′ is further provided at an output of the attenuator. When an impedance of a load connected to Vo is sufficiently higher than a parallel impedance of R3′ and R4′, the buffer amplifier Ub′ may be omitted.

In the temperature coefficient circuits 300 and 400 in FIGS. 4 and 5, when the gain of Ub′ is 1 (in the case of the temperature coefficient circuit 400), the gain G is represented by the formula 3. At the reference temperature, when (R3:R3′)=(R4:R4′) and the gain of Ub′=1, the gain G becomes 1 (G=1). For example, when R4 is used as the temperature coefficient resistor, the temperature coefficient of the gain G is {R3/(R3+R4)} times of the temperature coefficient resistor.

$$G = \frac{R {3}^{′}}{R {3}^{′} + R {4}^{′}} \times \frac{R 3 + R 4}{R 3} = ( 1 - \frac{R {4}^{′}}{R {3}^{′} + R {4}^{′}} ) \times ( 1 + \frac{R 4}{R 3} ) \qquad ( Formula 3 )$$

In the temperature coefficient circuits 300 and 400 in FIGS. 4 and 5, for each case where the temperature coefficient resistor is set to R3, R4, R3′ or R4′, directions of the temperature coefficients of the temperature coefficient resistor and the amplification factor, and a relationship between the temperature coefficients of the temperature coefficient resistor and the amplification factor are shown in Table 3. When the temperature coefficient resistor is set to R3, the directions of the temperature coefficients of the temperature coefficient resistor and the amplification factor are the opposite directions, and the relationship between the temperature coefficients of the temperature coefficient resistor and the amplification factor is a non-linear relationship. When the temperature coefficient resistor is set to R4, the directions of the temperature coefficients of the temperature coefficient resistor and the amplification factor are the same directions, and the relationship between the temperature coefficients of the temperature coefficient resistor and the amplification factor is a linear relationship. When the temperature coefficient resistor is set to R3′, the directions of the temperature coefficients of the temperature coefficient resistor and the amplification factor are the opposite directions, and the relationship between the temperature coefficients of the temperature coefficient resistor and the amplification factor is a non-linear relationship. When the temperature coefficient resistor is set to R4′, the directions of the temperature coefficients of the temperature coefficient resistor and the amplification factor are the same directions, and the relationship between the temperature coefficients of the temperature coefficient resistor and the amplification factor is a non-linear relationship.

TABLE 3

| | Directions of Temperature | Relationship Between |
|---|---|---|
| | Coefficients of | Temperature Coefficients of |
| Position of | Temperature | Temperature |
| Temperature | Coefficient Resistor and | Coefficient Resistor |
| Coefficient | Temperature Coefficients | and Temperature Coefficients |
| Resistor | of Amplification Factor | of Amplification Factor |
| R3 | Opposite Directions | Non-linear relationship |
| R4 | Same Directions | Linear relationship |
| R3′ | Opposite Directions | Non-linear relationship |
| R4′ | Same Directions | Non-linear relationship |

Since the temperature coefficient resistor with a larger temperature coefficient than the temperature coefficient of the gain G can be used commonly for the temperature coefficient circuits 300 and 400 in FIGS. 4 and 5, an effect of the temperature coefficient of another usual resistor can be made relatively small. In addition, the case of the gain G=1 is particularly useful because it is easy to add a temperature coefficient circuit to an output or the like of an existing circuit. Further, even when the gain of the buffer amplifier Ub′ is not 1(G≠1), there is a case in which the gain of the amplifier circuit can be 1 (G=1) by a combination of resistance values.

In the temperature coefficient circuit 300 in FIG. 4, since the maximum outputs of the operational amplifier U and Vo are the same, a large dynamic range can be secured. When it is desired to increase an input impedance, a buffer amplifier (not shown) may be added between Vi and R4′.

In the temperature coefficient circuit 400 in FIG. 5, since the resistor is not divided ahead of the input of the operational amplifier U, when an input signal level is low, it can be made to have low noise. Also, the input impedance is high.

As described above, in the circuits in FIG. 1 and FIGS. 3 to 5, circuits in which any one or more resistors are set as the temperature coefficient resistor are collectively referred to as “temperature coefficient circuits”. A circuit in which a temperature coefficient resistor is not used is a simple amplifier circuit.

When the temperature coefficient resistors are used for two resistors in which the directions of the temperature coefficients of the temperature coefficient resistor and the amplification factor are the same directions or for two resistors in which the directions of the temperature coefficients are the opposite directions, the temperature coefficient is increased, and when the temperature coefficient resistors are used for resistors in which the same direction and the opposite direction are mixed, the temperature coefficient is reduced.

(Variation of Variable Resistor)

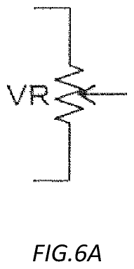

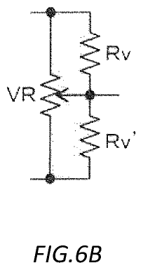

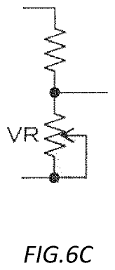

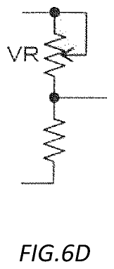

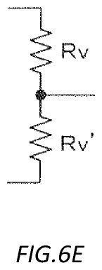

As shown in FIG. 6A, a variable resistor is shown as VR alone, as a general rule, throughout. As another example of the variable resistor, variations shown in FIGS. 6B to 6E are possible. In FIG. 6B, Rv and Rv′ are a circuit for stabilizing an input potential and the like of the buffer amplifier Ub when contact of a slider of the variable resistor VR is lost, and it is optional to add the same. For both Rv and Rv′, it is common to use resistors of the same value that is sufficiently larger than that of the variable resistor VR, but the present invention is not limited thereto. As shown in FIGS. 6C and 6D, it is also possible to configure a combination of the variable resistor VR and a fixed resistor. In FIG. 6E, it is assumed that a configuration in which either or both of the fixed resistor Rv and the fixed resistor Rv′ are made changeable and variable is also included in the variable resistor.

In addition, it is assumed that a configuration in which the resistance value or resistance ratio is digitally controlled using a digital potentiometer, a multiplying DA or the like is also included in the variable resistor VR.

In addition, it is assumed that a configuration in which a fixed resistor is connected in series or parallel to the variable resistor VR configures a variable resistor as a whole, and the configuration can be applied to variable resistors in all circuits of the present invention.

### First Embodiment

(Amplifier Circuit with Variable Temperature Coefficient of Gain (Inverting Amplifier Circuit, One Direction))

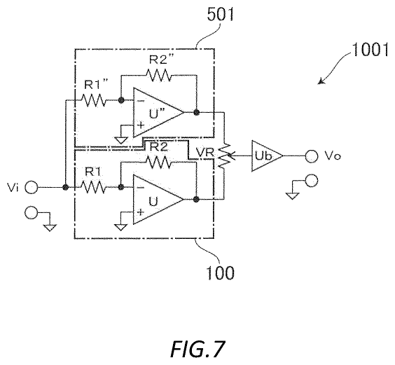

A circuit in FIG. 7 is an amplifier circuit 1001 with a variable temperature coefficient of a gain, in which a variable resistor VR is connected between a first signal and a second signal having temperature coefficients of an amplification factor different from each other, a variable output of the variable resistor VR is connected to an input of a buffer amplifier Ub, and an output of the buffer amplifier Ub is used as an output Vo. The first signal is an output of the temperature coefficient circuit 100, and the second signal is an output of another amplifier circuit 501.

The gain G of this circuit 1001 is expressed by the formula 4 when the gain of Ub is 1. In order to make the first signal and the second signal equal at the reference temperature, (R1:R2)=(R1″:R2″) is required at the reference temperature. When (R1≠∞ and R2≠0) and (R1″≠∞ and R2″≠0), the gain is smaller than 0 (G<0).

$$G = - \frac{R 2}{R 1} = - \frac{R {2}^{″}}{R {1}^{″}} \qquad ( Formula 4 )$$

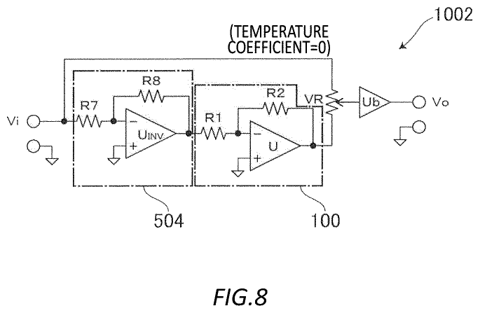

A circuit in FIG. 8 is an amplifier circuit 1002 with a variable temperature coefficient of a gain, in which a variable resistor VR is connected between a first signal and a second signal having temperature coefficients of an amplification factor different from each other, a variable output of the variable resistor VR is connected to an input of a buffer amplifier Ub, and an output of the buffer amplifier Ub is used as an output Vo. The first signal is an output of the temperature coefficient circuit 100, and the second signal is an input of the amplifier circuit 1002 with a variable temperature coefficient of a gain.

In the circuit in FIG. 8, an inverting amplifier circuit 504 configured by a gain resistor R7, a feedback resistor R8 and an operational amplifier U_{INV}, and the temperature coefficient circuit 100 are connected in series. The connection order of the inverting amplifier circuit 504 and the temperature coefficient circuit 100 may be interchanged. The temperature coefficient circuit 100 also performs inverting amplification, and is connected to the inverting amplifier circuit 504, so that the amplifier circuit 1002 is configured as a non-inverting amplifier circuit as a whole.

The gain G of this circuit 1002 is expressed by the formula 5 when the gain of Ub is 1. At the reference temperature, it is necessary that the gain should be 1 (G=1) when (R1:R2)=(R8:R7), i.e., the gain of Ub is 1.

$$G = \frac{R 2}{R 1} \times \frac{R 8}{R 7} \qquad ( Formula 5 )$$

In the amplifier circuits 1001 and 1002 shown in FIGS. 7 and 8, for each case where the temperature coefficient resistor is set to R1 or R1″ and R2 or R2″, directions of the temperature coefficients of the temperature coefficient resistor and the temperature coefficients of the absolute value of the amplification factor, and a relationship between the temperature coefficients of the temperature coefficient resistor and the temperature coefficients of the absolute value of the amplification factor are shown in Table 4. (Note that, when the temperature coefficient resistor is set to either R1″ or R2″, the circuit 501 and the circuit 100 are interchanged to the temperature coefficient circuit and the amplifier circuit.) When the temperature coefficient resistor is set to R1 or R1″, the directions of the temperature coefficients of the temperature coefficient resistor and the temperature coefficients of the absolute value of the amplification factor are the opposite directions, and the relationship between the temperature coefficients of the temperature coefficient resistor and the temperature coefficients of the absolute value of the amplification factor is a non-linear relationship (inversely proportional). When the temperature coefficient resistor is set to R2 or R2″, the directions of the temperature coefficients of the temperature coefficient resistor and the temperature coefficients of the absolute value of the amplification factor are the same directions, and the relationship between the temperature coefficients of the temperature coefficient resistor and the temperature coefficients of the absolute value of the amplification factor is a linear relationship (proportional). When the temperature coefficient is variable in only one direction, as a general rule, the temperature coefficient resistor is used for any one of R1, R1″, R2 or R2″.

TABLE 4

| | Directions of Temperature | Relationship Between |
|---|---|---|
| | Coefficients of Temperature | Temperature Coefficients of |
| Position of | Coefficient Resistor and | Temperature Coefficient |
| Temperature | Temperature Coefficients of | Resistor and Temperature |
| Coefficient | Absolute Value of | Coefficients of Absolute |
| Resistor | Amplification Factor | Value of Amplification Factor |
| R1 or R1″ | Opposite Directions | Non-linear relationship |
| | | (inversely proportional) |
| R2 or R2″ | Same Directions | Linear relationship |
| | | (proportional) |

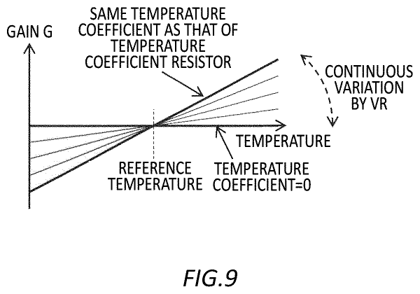

FIG. 9 is a diagram showing temperature dependence of the gain G when R2 is set as a temperature coefficient resistor in the amplifier circuit 1002 in FIG. 8. From the temperature coefficient=0 to the same temperature coefficient as that of the temperature coefficient resistor, the temperature dependence can be made continuously variable by the variable resistor VR.

### Second Embodiment

(Amplifier Circuit with Variable Temperature Coefficient of Gain (Non-Inverting Amplifier Circuit, One Direction))

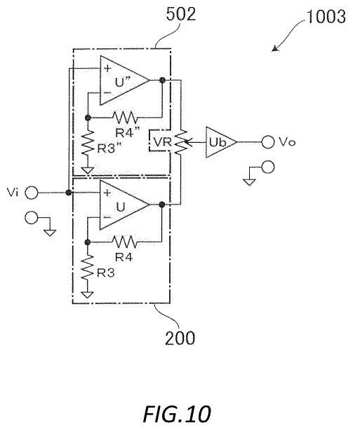

A circuit in FIG. 10 is an amplifier circuit 1003 with a variable temperature coefficient of a gain, in which a variable resistor VR is connected between a first signal and a second signal having temperature coefficients of an amplification factor different from each other, a variable output of the variable resistor VR is connected to an input of a buffer amplifier Ub, and an output of the buffer amplifier Ub is used as an output Vo. The first signal is an output of the temperature coefficient circuit 200, and the second signal is an output of another amplifier circuit 502.

The gain G of this circuit 1003 is represented by the formula 6 when the gain of Ub is 1. In order to make the first signal and the second signal equal at the reference temperature, (R3:R4)=(R3″:R4″) is required at the reference temperature. When (R3≠∞ and R4≠0), (R3″≠∞ and R4″≠0) and the gain of Ub≥1, the gain is greater than 1 (G>1).

$$G = 1 + \frac{R 4}{R 3} = 1 + \frac{R {4}^{″}}{R {3}^{″}} \qquad ( Formula 6 )$$

In the amplifier circuit 1003 in FIG. 10, for each case where the temperature coefficient resistor is set to R3 or R3″ and R4 or R4″, directions of the temperature coefficients of the temperature coefficient resistor and the amplification factor, and a relationship between the temperature coefficients of the temperature coefficient resistor and of the amplification factor are shown in Table 5. (Note that, when the temperature coefficient resistor is set to either R3″ or R4″, the circuit 502 and the circuit 200 are interchanged to the temperature coefficient circuit and the amplifier circuit.) When the temperature coefficient resistor is set to R3 or R3″, the directions of the temperature coefficients of the temperature coefficient resistor and the amplification factor are the opposite directions, and the relationship between the temperature coefficients of the temperature coefficient resistor and the amplification factor is a non-linear relationship. When the temperature coefficient resistor is set to R4 or R4″, the directions of the temperature coefficients of the temperature coefficient resistor and the amplification factor are the same directions, and the relationship between the temperature coefficients of the temperature coefficient resistor and the amplification factor is a linear relationship. When the temperature coefficient is variable in only one direction, as a general rule, the temperature coefficient resistor is used for any one of R3, R3″, R4 or R4″.

TABLE 5

| | Directions of Temperature | Relationship Between |
|---|---|---|
| | Coefficients of | Temperature Coefficients |
| | Temperature | of Temperature |
| Position of | Coefficient Resistor | Coefficient Resistor |
| Temperature | and Temperature | and Temperature |
| Coefficient | Coefficients | Coefficients of |
| Resistor | of Amplification Factor | Amplification Factor |
| R3 or R3″ | Opposite Directions | Non-linear relationship |
| R4 or R4″ | Same Directions | Linear relationship |

### Third Embodiment

(Amplifier Circuit with Variable Temperature Coefficient of Gain (Non-Inverting Amplifier Circuit with Gain G=1, One Direction))

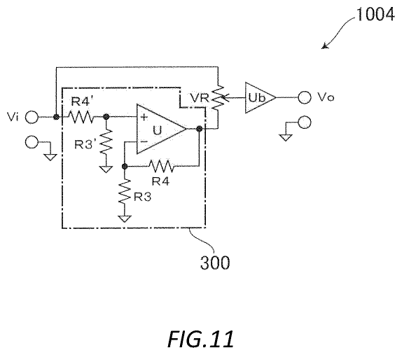

A circuit in FIG. 11 is an amplifier circuit 1004 with a variable temperature coefficient of a gain, in which a variable resistor VR is connected between a first signal and a second signal having temperature coefficients of an amplification factor different from each other, a variable output of the variable resistor VR is connected to an input of a buffer amplifier Ub, and an output of the buffer amplifier Ub is used as an output Vo. The first signal is an output of the temperature coefficient circuit 300, and the second signal is an input of the amplifier circuit 1004 with a variable temperature coefficient of a gain.

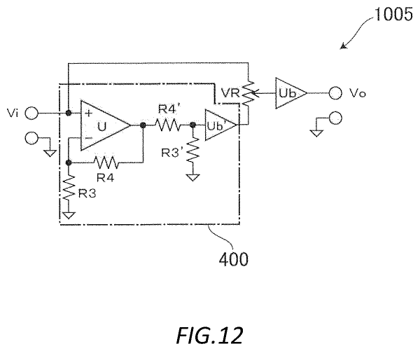

A circuit in FIG. 12 is an amplifier circuit 1005 with a variable temperature coefficient of a gain, in which a variable resistor VR is connected between a first signal and a second signal having temperature coefficients of an amplification factor different from each other, a variable output of the variable resistor VR is connected to an input of a buffer amplifier Ub, and an output of the buffer amplifier Ub is used as an output Vo. The first signal is an output of the temperature coefficient circuit 400, and the second signal is an input of the amplifier circuit 1005 with a variable temperature coefficient of a gain.

The gain G of these circuits 1004 and 1005 is expressed by the formula 7 when the gain of Ub and Ub′ (in the case of the circuit 1005) is 1. In order to make the first signal and the second signal equal at the reference temperature, (R3:R4)=(R3′:R4′) is required at the reference temperature, and the gain G is 1 (G=1) when the gains of Ub and Ub′ are 1.

$$G = \frac{R {3}^{′}}{R {3}^{′} + R {4}^{′}} \times \frac{R 3 + R 4}{R 3} \qquad ( Formula 7 )$$

In the amplifier circuits 1004 and 1005 in FIGS. 11 and 12, for each case where the temperature coefficient resistor is set to R3, R4, R3′ or R4′, directions of the temperature coefficients of the temperature coefficient resistor and the amplification factor, and a relationship between the temperature coefficients of the temperature coefficient resistor and the amplification factor are shown in Table 6. When the temperature coefficient resistor is set to R3, the directions of the temperature coefficients of the temperature coefficient resistor and the amplification factor are the opposite directions, and the relationship between the temperature coefficients of the temperature coefficient resistor and the amplification factor is a non-linear relationship. When the temperature coefficient resistor is set to R4, the directions of the temperature coefficients of the temperature coefficient resistor and the amplification factor are the same directions, and the relationship between the temperature coefficients of the temperature coefficient resistor and the amplification factor is a linear relationship. When the temperature coefficient resistor is set to R3′, the directions of the temperature coefficients of the temperature coefficient resistor and the amplification factor are the opposite directions, and the relationship between the temperature coefficients of the temperature coefficient resistor and the amplification factor is a non-linear relationship. When the temperature coefficient resistor is set to R4′, the directions of the temperature coefficients of the temperature coefficient resistor and the amplification factor are the same directions, and the relationship between the temperature coefficients of the temperature coefficient resistor and the amplification factor is a non-linear relationship.

TABLE 6

| | Directions of | |
|---|---|---|
| | Temperature | |
| | Coefficients of | Relationship Between |
| | Temperature | Temperature |
| | Coefficient | Coefficients of |
| | Resistor and | Temperature |
| Position of | Temperature | Coefficient Resistor |
| Temperature | Coefficients of | and Temperature |
| Coefficient | Amplification | Coefficients of |
| Resistor | Factor | Amplification Factor |
| R3 | Opposite Directions | Non-linear relationship |
| R4 | Same Directions | Linear relationship |
| R3′ | Opposite Directions | Non-linear relationship |
| R4′ | Same Directions | Non-linear relationship |

### Fourth Embodiment

(Amplifier Circuit with Variable Temperature Coefficient of Gain (Non-Inverting Amplifier Circuit with Gain G=1, Two Directions))

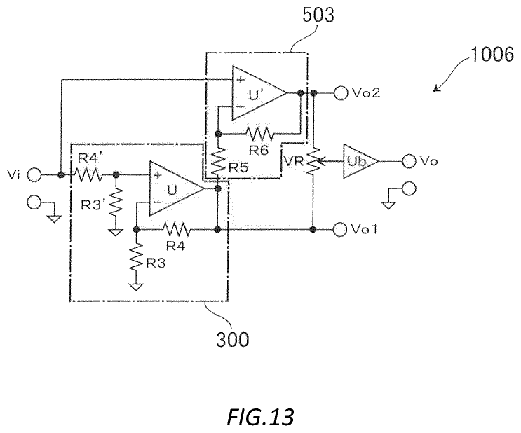

A circuit in FIG. 13 is an amplifier circuit 1006 with a variable temperature coefficient of a gain, in which a variable resistor VR is connected between a first signal Vo1 and a second signal Vo2 having temperature coefficients of an amplification factor different from each other, a variable output of the variable resistor VR is connected to an input of a buffer amplifier Ub, and an output of the buffer amplifier Ub is used as an output. The first signal Vo1 is an output of the temperature coefficient circuit 300, and the second signal Vo2 is an output of the temperature coefficient inverting circuit 503.

The gain G of this circuit 1006 is expressed by the formula 8 when the gain of Ub is 1. In order to make the first signal Vo1 and the second signal Vo2 equal at the reference temperature, (R3:R4)=(R3′:R4′) is required at the reference temperature, and the gain is 1 (G=1) when the gain of Ub is 1. It is assumed that R5=R6.

$$G = \frac{R {3}^{′}}{R {3}^{′} + R {4}^{′}} \times \frac{R 3 + R 4}{R 3} \qquad ( Formula 8 )$$

When the gain G=1 at the reference temperature, α=temperature coefficient of Vo1/Vi, Δt=temperature difference from the reference temperature, and R5=R6, Vo1 and Vo2 are represented by the formulas 9 and 10, respectively. That is, Vo1 and Vo2 have opposite temperature coefficients.

$$Vo 1 = Vi \cdot ( 1 + α \cdot Δ t ) \qquad ( Formula 9 )$$

$$Vo 2 = 2 \cdot Vi - Vo 1 = 2 \cdot Vi - Vi \cdot ( 1 + α \cdot Δ t ) = Vi \cdot ( 1 + α \cdot Δ t ) \qquad ( Formula 10 )$$

The amplifier circuit 1006 is a circuit in which the temperature coefficient inverting circuit 503 is added to the amplifier circuit 1004, but a circuit in which the temperature coefficient inverting circuit 503 is added to the amplifier circuit 1002 or the amplifier circuit 1005 can also be configured similarly.

In the amplifier circuit 1006 in FIG. 13, for each case where the temperature coefficient resistor is set to R3, R4, R3′ or R4′, directions of the temperature coefficients of the temperature coefficient resistor and Vo1/Vi, directions of the temperature coefficients of the temperature coefficient resistor and Vo2/Vi, and a relationship between the temperature coefficients of the temperature coefficient resistor and the amplification factor are shown in Table 7. When the temperature coefficient resistor is set to R3, the directions of the temperature coefficients of the temperature coefficient resistor and Vo1/Vi are the opposite directions, and the directions of the temperature coefficients of the temperature coefficient resistor and Vo2/Vi are the same directions, and the relationship of the temperature coefficients of the temperature coefficient resistor and the amplification factor is a non-linear relationship. When the temperature coefficient resistor is set to R4, the directions of the temperature coefficients of the temperature coefficient resistor and Vo1/Vi are the same directions, and the directions of the temperature coefficients of the temperature coefficient resistor and Vo2/Vi are the opposite directions, and the relationship of the temperature coefficients of the temperature coefficient resistor and the amplification factor is a linear relationship. When the temperature coefficient resistor is set to R3′, the directions of the temperature coefficients of the temperature coefficient resistor and Vo1/Vi are the opposite directions, and the directions of the temperature coefficients of the temperature coefficient resistor and Vo2/Vi are the same directions, and the relationship of the temperature coefficients of the temperature coefficient resistor and the amplification factor is a non-linear relationship. When the temperature coefficient resistor is set to R4′, the directions of the temperature coefficients of the temperature coefficient resistor and Vo1/Vi are the same directions, and the directions of the temperature coefficients of the temperature coefficient resistor and Vo2/Vi are the opposite directions, and the relationship of the temperature coefficients of the temperature coefficient resistor and the amplification factor is a non-linear relationship.

| | | | Relationship |
|---|---|---|---|
| | | | Between of |
| | | Directions of | Temperature |
| | Directions of | Temperature | Coefficients |
| | Temperature | Coefficients | of Temperature |
| | Coefficients | of | Coefficient |
| Position of | of Temperature | Temperature | Resistor and |
| Temperature | Coefficient | Coefficient | Temperature |
| Coefficient | Resistor | Resistor | Coefficients of |
| Resistor | and Vo1/Vi | and Vo2/Vi | Amplification Factor |
| R3 | Opposite | Same | Non-linear |
| | Directions | Directions | relationship |
| R4 | Same | Opposite | Linear relationship |
| | Directions | Directions | |
| R3′ | Opposite | Same | Non-linear relationship |
| | Directions | Directions | |
| R4′ | Same | Opposite | Non-linear relationship |
| | Directions | Directions | |

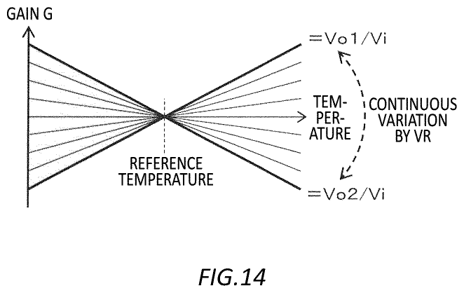

FIG. 14 is a diagram showing temperature dependence of the gain G when R4 is set as a temperature coefficient resistor in the amplifier circuit 1006 in FIG. 13. From Vo2/Vi to Vo1/Vi, the temperature dependence can be made continuously variable by the variable resistor VR.

### Fifth Embodiment

(Amplifier Circuit with Variable Temperature Coefficient of Gain (Non-Inverting Amplifier Circuit with Gain G>1, Two Directions))

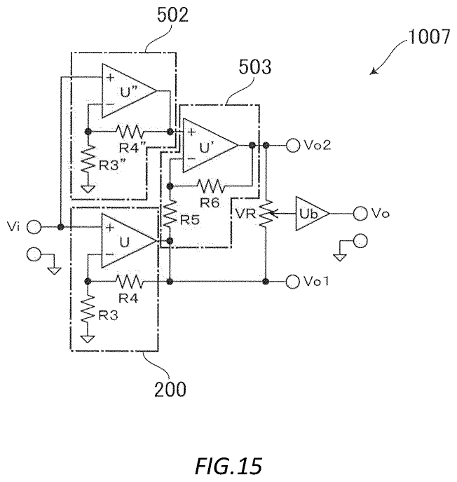

A circuit in FIG. 15 is an amplifier circuit 1007 with a variable temperature coefficient of a gain, in which a variable resistor VR is connected between a first signal Vo1 and a second signal Vo2 having temperature coefficients of an amplification factor different from each other, a variable output of the variable resistor VR is connected to an input of a buffer amplifier Ub, and an output of the buffer amplifier Ub is used as an output Vo. The first signal Vo1 is an output of the temperature coefficient circuit 200, and the second signal Vo2 is an output of the temperature coefficient inverting circuit 503.

In the temperature coefficient inverting circuit 503, a non-inverting input of the operational amplifier U′ configuring the temperature coefficient inverting circuit 503 is connected to an output of another amplifier circuit 502, an inverting input of the operational amplifier U′ configuring the temperature coefficient inverting circuit 503 is connected to one end of a feedback resistor R6 and one end of a gain resistor R5, an output of the operational amplifier U′ configuring the temperature coefficient inverting circuit 503 is connected to an opposite end of the feedback resistor R6, an output of the temperature coefficient circuit 200 is connected to an opposite end of the gain resistor R5, and the feedback resistor R6 and the gain resistor R5 have substantially the same resistance values.

The gain G of this circuit 1007 is expressed by the formula 11 when the gain of Ub is 1. In order to make the first signal Vo1 and the second signal Vo2 equal at the reference temperature, it is made that (R3:R4)=(R3″:R4″) at the reference temperature. When (R3≠∞ and R4≠0), (R3″≠∞ and R4″≠0) and the gain of Ub≥1, the gain is greater than 1 (G>1). It is assumed that R5=R6. For R3″ and R4″, a temperature coefficient resistor is not used.

$$G = 1 + \frac{R 4}{R 3} = 1 + \frac{R {4}^{″}}{R {3}^{″}} \qquad ( Formula 11 )$$

When the gain G=1 at the reference temperature, α=temperature coefficient of Vo1/Vi, Δt=temperature difference from the reference temperature, and R5=R6, if 1+(R4/R3)=1+(R4″/R3″)=A at the reference temperature, Vo1 and Vo2 are represented by the formulas 12 and 13, respectively. That is, Vo1 and Vo2 have opposite temperature coefficients.

$$Vo 1 = Vi \cdot A \cdot ( 1 + α \cdot Δ t ) \qquad ( Formula 12 )$$

$$Vo 2 = 2 \cdot Vi \cdot A - Vo 1 = 2 \cdot Vi \cdot A - Vi \cdot A \cdot ( 1 + α \cdot Δ t ) = Vi \cdot A \cdot ( 1 + α \cdot Δ t ) \qquad ( Formula 13 )$$

The amplifier circuit 1007 is a circuit in which the temperature coefficient inverting circuit 503 is added to the amplifier circuit 1003.

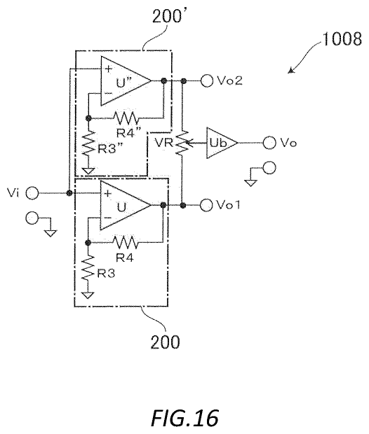

A circuit in FIG. 16 is an amplifier circuit 1008 with a variable temperature coefficient of a gain, in which a variable resistor VR is connected between a first signal Vo1 and a second signal Vo2 having temperature coefficients of an amplification factor different from each other, a variable output of the variable resistor VR is connected to an input of a buffer amplifier Ub, and an output of the buffer amplifier Ub is used as an output Vo. The first signal Vo1 is an output of the temperature coefficient circuit 200, and the second signal Vo2 is an output of the temperature coefficient circuit 200′.

The gain G of this circuit 1008 is expressed by the formula 14 when the gain of Ub is 1. In order to make the first signal Vo1 and the second signal Vo2 equal at the reference temperature, (R3:R4)=(R3″:R4″) is required at the reference temperature. When (R3≠∞ and R4≠0), (R3″≠∞ and R4″≠0) and the gain of Ub≥1, the gain is greater than 1 (G>1).

$$G = 1 + \frac{R 4}{R 3} = 1 + \frac{R {4}^{″}}{R {3}^{″}} \qquad ( Formula 14 )$$

The amplifier circuit 1008 has the same circuit configuration as the amplifier circuit 1003, but the temperature coefficients of Vo1 and Vo2 are reversed by using the temperature coefficient resistors for either (R3 and R4″) or (R3″ and R4). Compared with the amplifier circuit 1007, the temperature coefficient resistor is increased by one, and the operational amplifier is reduced by one.

### Sixth Embodiment

(Amplifier Circuit with Variable Temperature Coefficient of Gain (Inverting Amplifier Circuit with Gain G<0, Two Directions))

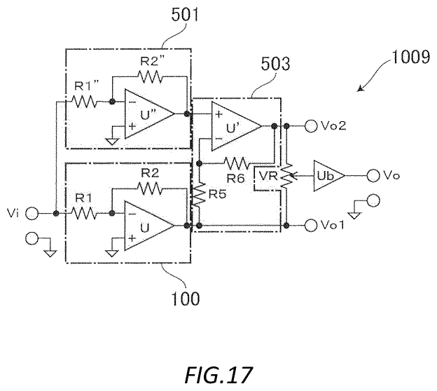

A circuit in FIG. 17 is an amplifier circuit 1009 with a variable temperature coefficient of a gain, in which a variable resistor VR is connected between a first signal Vo1 and a second signal Vo2 having temperature coefficients of an amplification factor different from each other, a variable output of the variable resistor VR is connected to an input of a buffer amplifier Ub, and an output of the buffer amplifier Ub is used as an output Vo. The first signal Vo1 is an output of the temperature coefficient circuit 100, and the second signal Vo2 is an output of the temperature coefficient inverting circuit 503.

In the temperature coefficient inverting circuit 503, a non-inverting input of the operational amplifier U′ configuring the temperature coefficient inverting circuit 503 is connected to an output of another amplifier circuit 501, an inverting input of the operational amplifier U′ configuring the temperature coefficient inverting circuit 503 is connected to one end of a feedback resistor R6 and one end of a gain resistor R5, an output of the operational amplifier U′ configuring the temperature coefficient inverting circuit 503 is connected to the opposite end of the feedback resistor R6, an output of the temperature coefficient circuit 200 is connected to the opposite end of the gain resistor R5, and the feedback resistor R6 and the gain resistor R5 have substantially the same resistance values.

The gain G of this circuit 1009 is expressed by the formula 15 when the gain of Ub is 1. In order to make the first signal Vo1 and the second signal Vo2 equal at the reference temperature, it is made that (R1:R2)=(R1″:R2″) at the reference temperature. When (R1≠∞ and R2≠0) and (R1″≠∞ and R2″≠0), the gain is smaller than 0 (G<0). It is assumed that R5=R6. For R1″ and R2″, a temperature coefficient resistor is not used.

$$G = - \frac{R 2}{R 1} = - \frac{R {2}^{″}}{R {1}^{″}} \qquad ( Formula 15 )$$

When the gain G=1 at the reference temperature, α=temperature coefficient of Vo1/Vi, Δt=temperature difference from the reference temperature, and R5=R6, if −R2/R1=−R2″/R1″=A at the reference temperature, Vo1 and Vo2 are represented by the formulas 16 and 17, respectively. That is, Vo1 and Vo2 have opposite temperature coefficients.

$$Vo 1 = Vi \cdot A \cdot ( 1 + α \cdot Δ t ) \qquad ( Formula 16 )$$

$$Vo 2 = 2 \cdot Vi \cdot A - Vo 1 = 2 \cdot Vi \cdot A - Vi \cdot A \cdot ( 1 + α \cdot Δ t ) = Vi \cdot A \cdot ( 1 - α \cdot Δ t ) \qquad ( Formula 17 )$$

An amplifier circuit 1009 is a circuit in which the temperature coefficient inverting circuit 503 is added to the amplifier circuit 1001.

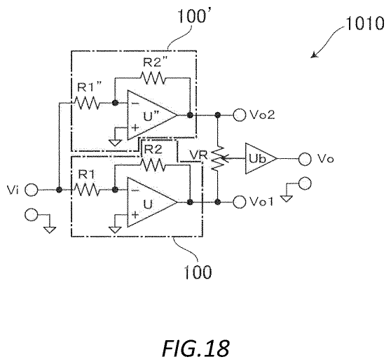

A circuit in FIG. 18 is an amplifier circuit 1010 with a variable temperature coefficient of a gain, in which a variable resistor VR is connected between a first signal Vo1 and a second signal Vo2 having temperature coefficients of an amplification factor different from each other, a variable output of the variable resistor VR is connected to an input of a buffer amplifier Ub, and an output of the buffer amplifier Ub is used as an output Vo. The first signal Vo1 is an output of the temperature coefficient circuit 100, and the second signal Vo2 is an output of the temperature coefficient circuit 100′.

The gain G of this circuit 1010 is expressed by the formula 15 when the gain of Ub is 1. In order to make the first signal Vo1 and the second signal Vo2 equal at the reference temperature, it is made that (R1:R2)=(R1″:R2″) at the reference temperature. When (R1≠∞ and R2≠0) and (R1″≠∞ and R2″≠0), the gain is smaller than 0 (G<0).

The amplifier circuit 1010 has the same circuit configuration as the amplifier circuit 1001, but the temperature coefficients of Vo1 and Vo2 are reversed by using the temperature coefficient resistors for either (R1 and R2″) or (R1″ and R2). Compared with the amplifier circuit 1009, the temperature coefficient resistor is increased by one, and the operational amplifier is reduced by one.

Hereinafter, Examples are described. However, the resistance values, the temperature coefficients and the like are not limited to the Examples.

### Example 1

(Realization of Smaller Temperature Coefficient)

(Circuit Similar to Amplifier Circuit 1004)

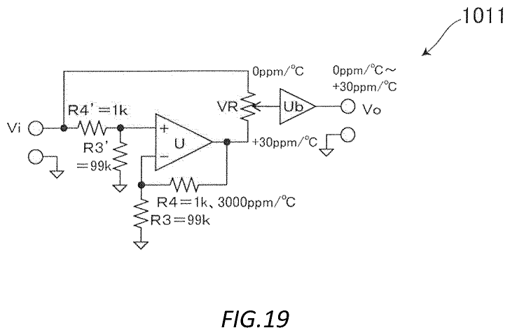

FIG. 19 is a diagram (amplifier circuit 1011) showing an example of the resistance value and temperature coefficient in the amplifier circuit 1004. It is assumed that a temperature coefficient of a usual resistor other than the temperature coefficient resistor (R4, in the example of the same drawing) is sufficiently smaller than 3000 ppm/° C. (for example, within ±50 ppm/° C.). A temperature coefficient smaller than the temperature coefficient of the usual resistor can be stably obtained. Note that, the effect of the temperature coefficient of the usual resistor is also reduced, and in the example of the same drawing, the effect becomes 1/100.

Compared with an amplifier circuit 1012 described later, when an input signal level is low, it can be made to have a low noise by reducing a value of a ratio of R4 to R3 (R4/R3) or a ratio of R4′ to R3′ (R4′/R3′).

Although the circuit similar to the amplifier circuit 1004 is exemplified here, this method or idea can be similarly applied to all other amplifier circuits with a variable temperature coefficient to stably obtain a small temperature coefficient.

### Example 2

(Realization of Smaller Temperature Coefficient)

(Modified Circuit of Amplifier Circuit 1004)

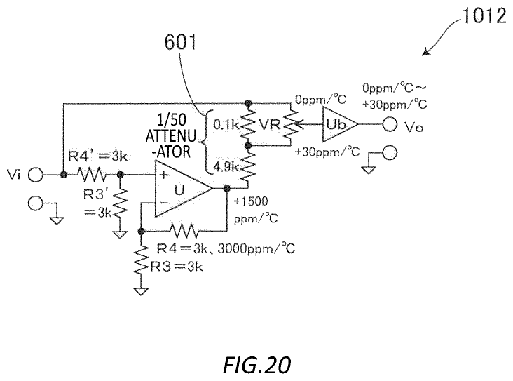

FIG. 20 is a modified circuit of the amplifier circuit 1004, showing an example (amplifier circuit 1012) of a configuration using an attenuator 601 (as an example, 1/50 attenuator). The attenuator 601 (0.1 kΩ and 4.9 kΩ) and the variable resistor VR configure a variable resistor as a whole. The variable resistor VR is set to have a resistance value (for example, 100 kΩ) sufficiently larger than 0.1 kΩ.

When the temperature coefficients of the two resistors used in the attenuator 601 are matched, a temperature coefficient smaller than the temperature coefficient of the usual resistor can be stably obtained, similarly to the amplifier circuit 1011.

Since the value of the ratio of R4 to R3 (R4/R3) or the ratio of R4′ to R3′ (R4′/R3′) is larger than that of the amplifier circuit 1011, a larger dynamic range can be secured.

Although the modified circuit of the amplifier circuit 1004 is exemplified here, this method or idea can be similarly applied to all other amplifier circuits with a variable temperature coefficient to stably obtain a small temperature coefficient.

### Example 3

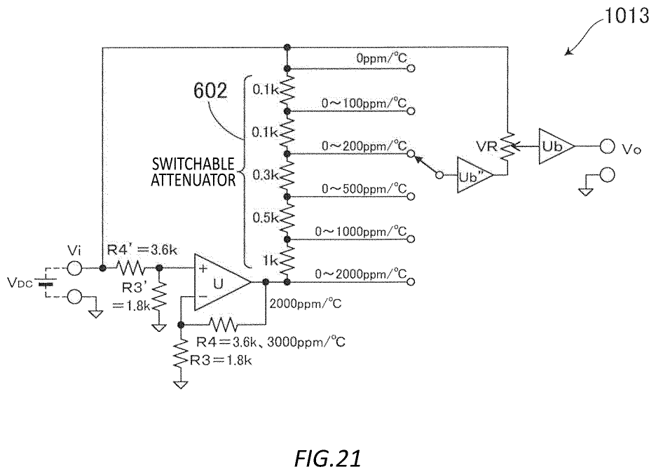

(Range Switching of Temperature Coefficient) FIG. 21 is a modified circuit (amplifier circuit 1013) of the amplifier circuit 1012, showing an example of a range switching circuit of a temperature coefficient of an amplification factor, in which a switchable attenuator 602 is used. The switchable attenuator 602, the buffer amplifier Ub″ and the variable resistor VR configure a variable resistor as a whole. When a direct voltage source V_{DC} is connected to Vi as shown by the dotted line, a range switching circuit of a temperature coefficient of a direct voltage can be realized. Various other realization methods of the range switching circuit of the temperature coefficient are also considered, such as switching a plurality of attenuators or combining and switching the temperature coefficient resistor Rt and the usual resistor Rc as shown in FIGS. 2A to 2C.

It is also effective to use a digital potentiometer, instead of the switchable attenuator 602. When a temperature coefficient of up to 2000 ppm/° C. is possible as in the example of the amplifier circuit 1013, for example, if a digital potentiometer capable of switching in 200 steps is used, the maximum value that can be continuously varied by the variable resistor VR can be selected in a unit of 10 ppm/° C. In this case, as an example, a range of 0 to 1280 ppm/° C. can also be realized. Further, using a digital potentiometer as the variable resistor VR is useful because both range switching and variation of the temperature coefficient can be digitally set.

When a resistance value of the variable resistor VR is set to a value (e.g., 200 kΩ) sufficiently larger than the resistance of the attenuator 602, the buffer amplifier Ub″ can be omitted.

Although the amplifier circuit 1013 capable of range switching is exemplified here, the method and idea of range switching can be similarly applied to all other amplifier circuits with a variable temperature coefficient. As an example, when the temperature coefficient inverting circuit 503 is added, the temperature coefficient variable range can be made positive-negative symmetric.

### Example 4

(Temperature Characteristic Compensation of IV Amplifier)

(Circuit Roughly Similar to Amplifier Circuit 1006)

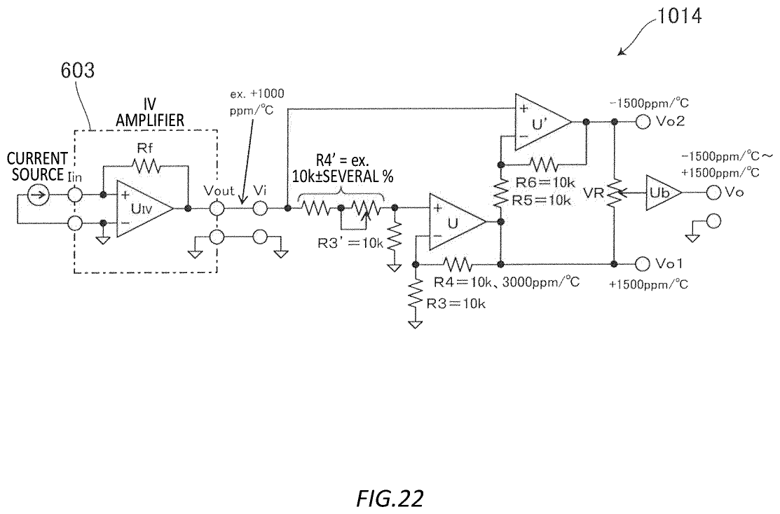

FIG. 22 is a diagram showing an example of a configuration of a temperature characteristic compensation circuit of an IV amplifier 603. In the IV amplifier 603 (current amplifier, current-voltage converting circuit), the current is converted into voltage with a relationship of Vout=Iin·Rf. In a highly sensitive IV amplifier, as an example, a high resistor such as 1 GΩ or 10 GΩ is used as Rf. However, since such a high resistor has a large temperature coefficient of, for example, hundreds of ppm/° C. to one thousand and hundreds of ppm/° C., the current amplification factor of the IV amplifier also has a similarly large temperature coefficient. In the amplifier circuit 1014, an example is shown in which by using a circuit similar to the amplifier circuit 1006, ±1500 ppm/° C. is made compensable, and is then set to −1000 ppm/° C. at VR, so that +1000 ppm/° C. of the input of the amplifier circuit 1014 (output Vout of the IV amplifier 603) is compensated.

This method or idea can be similarly applied to all other amplifier circuits with a variable temperature coefficient to compensate for the temperature characteristics of the amplifier (IV amplifier 603 as an example) to be compensated for the temperature coefficient of the amplification factor. In the same drawing, an example is shown in which the temperature coefficient resistor is used for R4 and R4′ is made partially variable. However, another resistor (in a circuit having R1, R2, and R1′, R2′, these resistors are also included) may also be used as the temperature coefficient resistor or made partially variable. When the temperature coefficient to be compensated is either positive or negative, the circuits of the amplifier circuits 1001 to 1005 may also be used instead of the amplifier circuit 1006.

A circuit or element having a temperature coefficient (for example, Rf of the IV amplifier 603) and a temperature coefficient resistor of a temperature coefficient compensation circuit (for example, R4 of the amplifier circuit 1014) are preferably brought as close to the same temperature as possible.

In order to be able to compensate for errors in R3, R3′ and R4, as shown in FIG. 22, a variable resistor is provided at a part of R4′. Assuming that the current applied from the current source to Iin is constant regardless of temperatures, only the temperature coefficient of the IV amplifier 603 may be compensated, or the temperature coefficient of the current source may also be compensated together. The current source may be alternating current or direct current.

### Example of Adjusting Procedure

1. At the reference temperature (for example, 25° C.), R4′ is adjusted so that Vi=Vo1.

2. At a desired temperature (e.g. 40° C.), the variable resistor VR is adjusted so that the voltage of Vo becomes equal to Vo1 at the reference temperature.

### Example 5

(Amplification Factor and Voltage Proportional to Absolute Temperature)

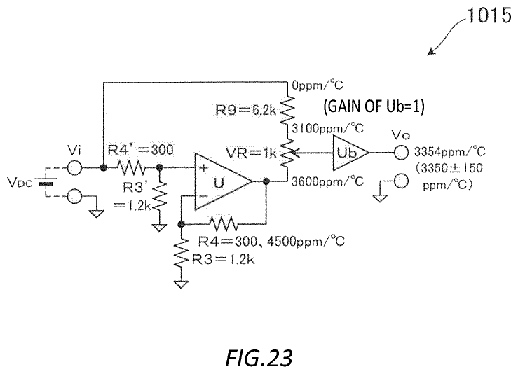

FIG. 23 is a diagram showing an example of a configuration of an amplifier circuit 1015 in which the amplification factor is proportional to the absolute temperature. R9 and the variable resistor VR configure a variable resistor as a whole. In equations representing characteristics of semiconductor devices, a part called q/(kT) often appears. Here, q=1.602E−19 (charge of electrons), k=1.38E−23 (Boltzmann constant), and T is an absolute temperature (K). When an amplification factor or voltage proportional to the absolute temperature T is used, in this equation, the term of the absolute temperature T is canceled out, and characteristics irrelevant to the temperature may be obtained in some cases. Note that, the temperature coefficient proportional to the absolute temperature T is about 3354 ppm/° C., based on 25° C. In FIG. 23, when a direct voltage source V_{DC} is connected to Vi as shown by the dotted line, a voltage having a temperature coefficient of about 3350±150 ppm/° C. can be obtained, and a voltage (about 3354 ppm/° C.) proportional to the absolute temperature can be obtained.

### Example 6

(Temperature Characteristic Compensation of Direct Voltage Source)

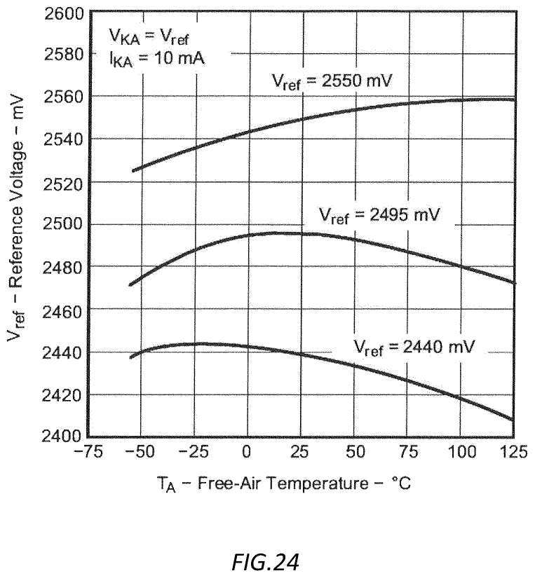

FIG. 24 shows a temperature characteristic of an output voltage of TL431 (Texas Instruments Incorporated), which is a direct voltage source IC commonly used by one skilled in the art (https://www.tij.co.jp/jp/lit/ds/symlink/t1431.pdf). It is perceived that the temperature coefficients are different due to variations in voltage Vref, at 25° C., of an embedded reference voltage source. Note that, in the specification of this IC, the maximum value of Vref at 25° C. is 2550 mV, and the minimum value is 2440 mV.

At the ambient temperature of 0 to 50° C., at Vref=2550 mV, the output voltage of the IC has a positive temperature coefficient of about 150 ppm/° C., and at Vref=2440 mV, the output voltage of the IC has a temperature coefficient of about −130 ppm/° C. That is, in this IC, if the temperature coefficient of about ±150 ppm/° C. can be compensated, the temperature characteristics can be compensated.

On the other hand, at Vref=2495 mV, the output voltage of the IC has a positive temperature coefficient at below 25° C., and has a negative temperature coefficient at 25° C. or higher. However, at the absolute values, the negative temperature coefficient at 25° C. or higher is larger. In this case, if the temperature coefficient can be compensated with a characteristic (V-shaped or inverted V-shaped) in which the positive and negative temperature coefficients change each other on the basis of a certain temperature as a boundary, the temperature characteristic can be compensated.

For example, in FIG. 24, at the ambient temperature of 0 to 50° C. of Vref=2440 mV, the temperature coefficient is not perfect in terms of the linearity, and has a slightly non-linear relationship. In this case, as an example, there is a case where, by using a temperature coefficient resistor for R1, the relationship between the temperature and the amplification factor is made inversely proportional, and more perfect temperature characteristic compensation can be realized. Further, there is a case where, by using a temperature coefficient resistor at another location where the relationship between the temperature coefficients of the temperature coefficient resistor and the amplification factor is a non-linear relationship, more perfect temperature characteristic compensation can be realized.

(Circuit Similar to Amplifier Circuit 1006)

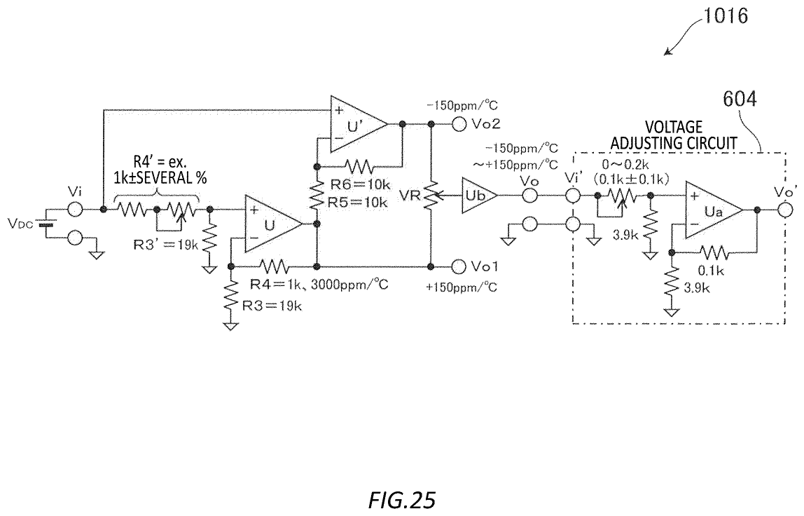

FIG. 25 is a diagram showing an example of a configuration of a circuit 1016 for compensating for ±150 ppm/° C. by using a circuit similar to the amplifier circuit 1006. In the example in FIG. 24, the maximum value of the voltage Vref, at 25° C., of the reference voltage source is 2550 mV, the minimum value is 2440 mV, and the nominal value is 2.5 V. That is, when a voltage adjusting circuit 604 capable of adjusting the amplification factor by about ±2.5% is added, the nominal value voltage can be obtained. An example of such a voltage adjusting circuit 604 is shown in FIG. 25 as an additional circuit of the amplifier circuit 1006, but it is optional to add the same.

### Example of Adjusting Procedure

Here, as shown in FIG. 25, it is assumed that a variable resistor is provided at a part of R4′ so that errors in R3, R3′ and R4 can be compensated.

1. At the reference temperature (for example, 25° C.), R4′ is adjusted so that Vi=Vo1. In the case where the voltage adjusting circuit 604 is added, the variable resistor of the voltage adjusting circuit 604 is further adjusted so that Vo′ becomes the nominal value voltage.

2. At a desired temperature (for example. 40° C.), the variable resistor VR is adjusted so that the voltage of Vo becomes equal to Vo1 at the reference temperature.

### Example 7

(V-Shaped Compensation and Inverted V-Shaped Compensation on Temperature Characteristics of Direct Voltage Source)

(Modified Circuit of Amplifier Circuit 1006)

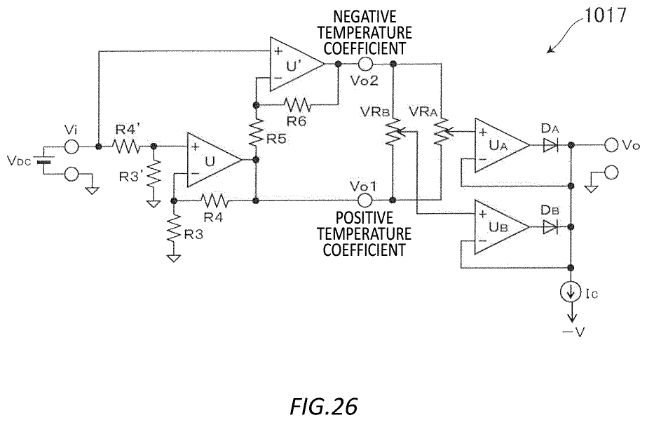

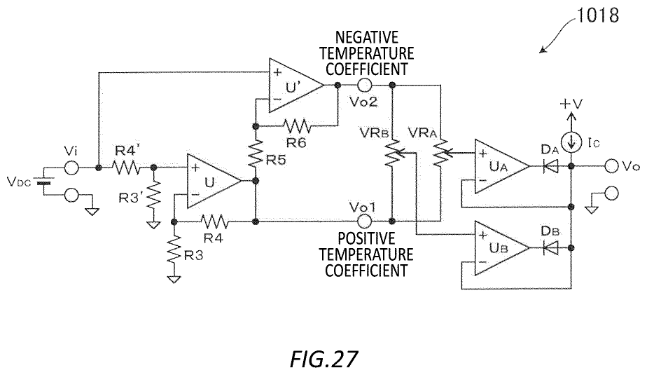

FIG. 26 is a modified circuit of the amplifier circuit 1006, showing an example of a configuration of a circuit 1017 configured to perform V-shaped compensation on the temperature characteristic of the direct voltage source V_{DC}. FIG. 27 is a modified circuit of the amplifier circuit 1006, showing an example of a configuration of a circuit 1018 configured to perform inverted V-shaped compensation on the temperature characteristic of the direct voltage source V_{DC}. In FIGS. 26 and 27, the description of the positive temperature coefficient of the Vo1 portion and the negative temperature coefficient of the Vo2 portion refers to a case where a temperature coefficient resistor having a positive temperature coefficient is used as R4.

A direct voltage source V_{DC} having a temperature coefficient in an output voltage is connected to an input, a first variable resistor VR_{A} and a second variable resistor VR_{B} are provided as a variable resistor, the buffer amplifier Ub is not provided, a variable output of the first variable resistor VR_{A} is connected to a non-inverting input of the first operational amplifier U_{A}, a variable output of the second variable resistor VR_{B} is connected to a non-inverting input of the second operational amplifier U_{B}, an output of the first operational amplifier U_{A} is connected to an inverting input of the first operational amplifier U_{A} via a first diode D_{A}, an output of the second operational amplifier U_{B} is connected to an inverting input of the second operational amplifier U_{B} via a second diode D_{B}, the inverting input of the first operational amplifier U_{A} and the inverting input of the second operational amplifier U_{B} are connected in common, a constant current source Ic or a resistor (not shown) is provided between the common connection and the voltage source (−V or +V), and the common connection is used as an output, so that the temperature coefficient of the direct voltage source V_{DC} is independently compensated and output at temperatures higher and lower than the reference temperature.

The constant current source Ic is provided for causing the current to flow through the first and second diode D_{A} and D_{B} and turning on the diodes. A resistor may be used instead.

Since either U_{A} or U_{B} operates in saturation, it is necessary to use operational amplifiers, in which a protection diode is not provided between the non-inverting input and the inverting input, for U_{A} and U_{B}.

In the circuit 1017, since a higher output voltage of U_{A} and U_{B} appears in Vo, V-shaped compensation is possible. In the circuit 1018, since a lower output voltage of U_{A} and U_{B} appears in Vo, inverted V-shaped compensation is possible.

FIGS. 26 and 27 exemplify the modified circuits of the amplifier circuit 1006. However, this method or idea can be similarly applied to all other amplifier circuits with a variable temperature coefficient having Vo1 and Vo2.

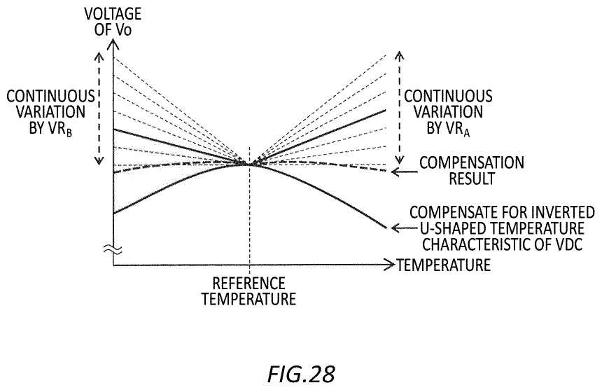

FIG. 28 shows the temperature dependence of the gain G when a temperature coefficient resistor having a positive temperature coefficient is used as R4, a slider of a variable resistor VR_{A} is set close to Vo1 and a slider of a variable resistor VR_{B} is set close to Vo2 in the circuit 1017 in FIG. 26. For example, an inverted U-shaped temperature characteristic of a direct voltage source V_{DC}, such as the characteristic of Vref=2449 mV in FIG. 24, can be compensated by continuous variations of the variable resistors VR_{A} and VR_{B} by using the V-shaped compensation of the circuit 1017.

### Example 8

(Temperature Coefficient Output of 0V at Reference Temperature)

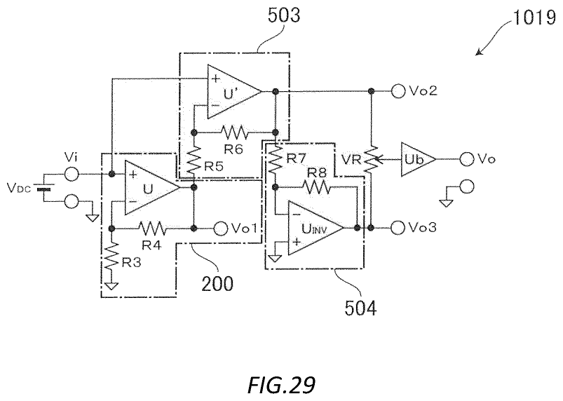

FIG. 29 is a diagram showing an example of a configuration of a circuit 1019 configured to perform a temperature coefficient output of 0 V at a reference temperature. At the reference temperature, R3=R4, R5=R6, and R7=R8. For R7 and R8, similar to R5 and R6, it is preferable to use a pair of resistors whose relative resistance difference and relative temperature coefficients are small. A circuit 200 is a temperature coefficient circuit and outputs a first signal Vo1. A second signal Vo2 is an output of the temperature coefficient inverting circuit 503, and a third signal Vo3 is a signal in which a polarity of the output of the temperature coefficient inverting circuit 503 is inverted by the inverting amplifier circuit 504. The circuit 1019 is a circuit in which a temperature coefficient of an output voltage is made variable using an amplifier circuit with a variable temperature coefficient of the gain G, in which a variable resistor VR is connected between the second signal Vo2 and the third signal Vo3 having temperature coefficients of an amplification factor different from each other. By connecting the direct voltage source V_{DC} to an input of the amplifier circuit 1019, a voltage with a variable temperature coefficient, which becomes a reference potential at the reference temperature, is generated.

When R4 is set as the temperature coefficient resistor, α=the temperature coefficient of the temperature coefficient resistor R4, and Δt=the temperature difference from the reference temperature, Vo1, Vo2 and Vo3 are expressed by the formulas 18 to 20, respectively. That is, Vo2 and Vo3 have opposite temperature coefficients.

$$Vo 1 = 2 Vi \cdot ( 1 + α \cdot Δ t ) \qquad ( Formula 18 )$$

$$Vo 2 = 2 \cdot Vi - Vo 1 = 2 \cdot Vi - 2 Vi \cdot ( 1 + α \cdot Δ t ) = - 2 Vi \cdot α \cdot Δ t \qquad ( Formula 19 )$$

$$Vo 3 = - Vo 2 = + 2 Vi \cdot α \cdot Δ t \qquad ( Formula 20 )$$

The circuit in FIG. 29 is an example of the circuit configuration, and another circuit configuration may be used as long as the temperature coefficient output of 0 V can be obtained at the reference temperature. It is only necessary to be able to obtain the second signal Vo2 and the third signal Vo3, which are 0V at the reference temperature and have temperature coefficients of the opposite directions, and to vary therebetween with the variable resistor VR.

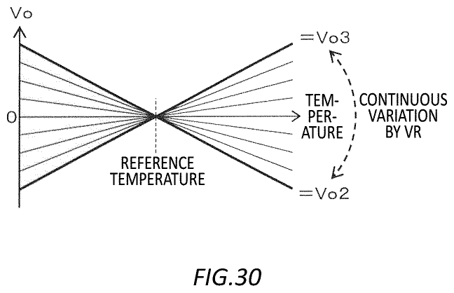

FIG. 30 is a diagram showing temperature dependence of the gain G when R4 is set as a temperature coefficient resistor in the amplifier circuit 1019 in FIG. 29. From Vo2 to Vo3, the temperature dependence can be made continuously variable by the variable resistor VR.

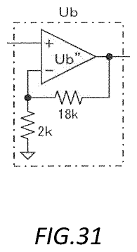

As a more specific example, when Vi: +2.5V, temperature coefficient of temperature coefficient resistor: 4000 ppm/° C., reference temperature: 25° C., and ambient temperature: 0 to 50° C. (i.e. 25±25° C.), Vo3 becomes ±0.5V (Vo3=2·2.5V·4000 ppm/° C.·±25° C.=±0.5V). When a larger temperature coefficient output is required, it is only necessary to make the gain of the buffer amplifier Ub larger than 1. As an example, when the buffer amplifier Ub is configured as shown in FIG. 31, the gain thereof is 10 times, and ±5V is obtained at 25±25° C.

### Example 9

(Temperature Drift Compensation 1 of High-speed OP Amplifier Using Temperature Coefficient Output of 0V at Reference Temperature)

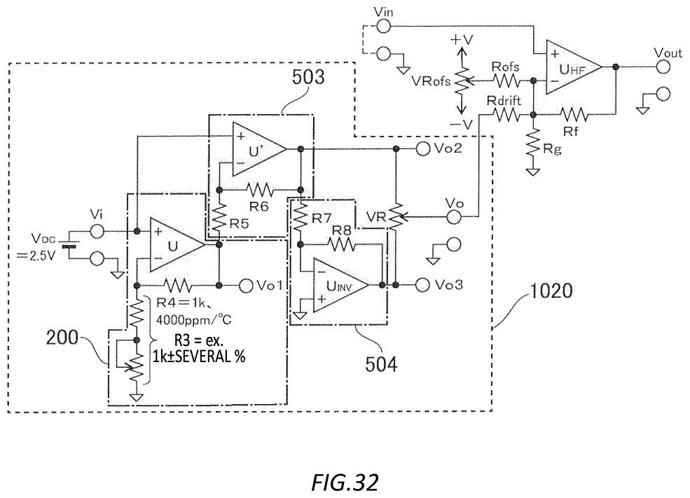

FIG. 32 is a diagram showing an example of a configuration of a circuit 1020 configured to perform temperature drift compensation of a high-speed OP amplifier using a temperature coefficient output of 0 V at a reference temperature. It is assumed that the temperature coefficient resistor R4 has 1 kΩ and 4000 ppm/° C. at the reference temperature. R3 is made adjustable by 1 kΩ±several %. It is preferable to set R5 and R6, and R7 and R8 as a pair of resistors in which the resistance values and temperature coefficients match, respectively. A second signal Vo2 is an output of the temperature coefficient inverting circuit 503, and a third signal Vo3 is a signal in which a polarity of the output of the temperature coefficient inverting circuit 503 is inverted by the inverting amplifier circuit 504. The circuit 1020 is a circuit in which a temperature coefficient output of 0V is performed at the reference temperature by using an amplifier circuit with a variable temperature coefficient of the gain G, in which a variable resistor VR is connected between the second signal Vo2 and the third signal Vo3 having temperature coefficients of an amplification factor different from each other. By connecting the direct voltage source V_{DC} to an input of the amplifier circuit 1020, a voltage with a variable temperature coefficient, which becomes a reference potential at the reference temperature, is generated. An output of the circuit that generates the voltage with a variable temperature coefficient, which becomes a reference potential at the reference temperature, is applied to an input of another amplifier circuit, and the temperature drift of another amplifier circuit is compensated.

A high-speed wideband operational amplifier (U_{HF} in FIG. 32) generally has such a tendency that an offset voltage, a bias current and temperature drifts thereof are large. Here, an example is shown in which the temperature drift of U_{HF} is also compensated by the modified circuit 1020 of the circuit 1019 in FIG. 29, in addition to general offset voltage compensation circuits (VRofs and Rofs). Rofs and Rdrift are selected with sufficiently larger resistance values than the gain resistor Rg so that a gain error of the high-speed operational amplifier does not occur. For this reason, in FIG. 32, the buffer amplifier Ub in FIG. 29 can be omitted.

When a temperature drift is not linear with respect to temperatures, for example, when the temperature drift changes in an inverted U-shape or an inverted V-shape around the reference temperature, the circuit between Vo1·Vo2 and Vo in the circuit 1017 in FIG. 27 is applied between Vo2·Vo3 and Vo to perform V-shaped compensation, so that more accurate offset compensation can be performed. In addition, when the temperature drift changes in a U-shape or a V-shape around the reference temperature, the circuit between Vo1·Vo2 and Vo in the circuit 1018 in FIG. 28 is applied to perform inverted V-shaped compensation, so that more accurate offset compensation can be performed.

### Example of Adjusting Procedure

Here, as shown in FIG. 32, it is assumed that a variable resistor is provided at a part of R3 so that an error in R4 can be compensated.

1. At the reference temperature (e.g. 25° C.), R3 is adjusted so that Vo=Vi. In this case, if R5 to R8 are accurate, Vo=Vo1=Vo2=0V.

2. Vin is connected to the reference potential (dotted line in FIG. 32), and the variable resistor VRofs is adjusted so that Vout=0V.

3. At the desired temperature (e.g. 40° C.), the variable resistor VR is adjusted so that Vout=0V.

### Example 10

(Temperature Drift Compensation 2 of High-speed OP Amplifier Using Temperature Coefficient Output of 0V at Reference Temperature)

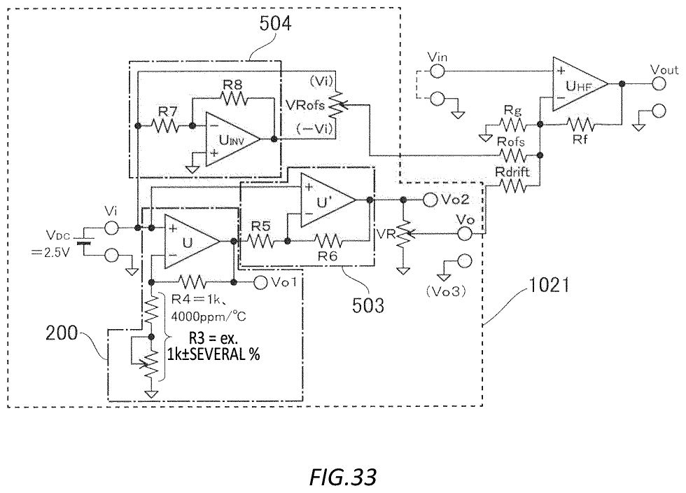

FIG. 33 is a diagram showing an example of a configuration of a circuit 1021 configured to perform temperature drift compensation of a high-speed OP amplifier using a temperature coefficient output of 0 V at a reference temperature. It is assumed that the temperature coefficient resistor R4 has 1 kΩ and 4000 ppm/° C. at the reference temperature. R3 is made variable by 1 kΩ±several %. It is preferable to set R5 and R6, and R7 and R8 as a pair of resistors in which the resistance values and temperature coefficients match, respectively. A second signal Vo2 is the output of the temperature coefficient inverting circuit 503, and a third signal Vo3 is the reference potential. The circuit 1021 is a circuit in which a temperature coefficient output of 0V is performed at the reference temperature by using an amplifier circuit with a variable temperature coefficient of the gain G, in which a variable resistor VR is connected between the second signal Vo2 and the third signal Vo3 having temperature coefficients of an amplification factor different from each other, and further includes an inverting amplifier circuit 504 additionally. By connecting the direct voltage source V_{DC} to an input of the amplifier circuit 1021, a voltage with a variable temperature coefficient, which becomes a reference potential at the reference temperature, is generated. An output of the circuit that generates the voltage with a variable temperature coefficient, which becomes a reference potential at the reference temperature, is applied to an input of another amplifier circuit, and the temperature drift of another amplifier circuit is compensated.

The circuit 1021 in FIG. 33 is obtained by applying a following modification to the circuit 1020 in FIG. 32.

In the case of U_{HF} of the same type, the temperature coefficient of drift is often set either positive or negative. In this case, as shown in FIG. 33, the inverting amplifier circuit for generating Vo3 may be omitted, and the side connected to Vo3 of the variable resistor VR may be connected to the reference potential. Note that, when the positive or negative temperature coefficient of the drift is opposite, R3 may be set as the temperature coefficient resistor, and R4 may be made variable by 1 kΩ±several %. (In FIG. 33, since the resistance value of R3 and the resistance value of R4 at the reference temperature are the same 1 kΩ, it is only necessary to simply change R3 and R4 each other.)

In the circuit 1020 in FIG. 32, the offset voltage is compensated using the positive and negative power supplies (+V and −V) of the operational amplifier, but it cannot be said that the power supply voltage of the operational amplifier is necessarily stable. In the circuit 1021 in FIG. 33, the more stable voltage source and the inverting amplifier circuit 504 (U_{INV}, R7, R8), which are connected to Vi, are used for more stable offset voltage compensation. Note that, when the offset of U_{HF} is determined to be either positive or negative, the inverting amplifier circuit 504 may be omitted in some cases by connecting the −Vi side of VRofs to the reference potential.

### Example of Adjusting Procedure

Here, as shown in FIG. 33, it is assumed that a variable resistor is provided at a part of R3 so that an error in R4 can be compensated.

1. At the reference temperature (e.g. 25° C.), R3 is adjusted so that Vo=Vi. In this case, if R5 to R8 are accurate, Vo=Vo1=Vo2=0V.

2. Vin is connected to the reference potential (dotted line in FIG. 32), and the variable resistor VRofs is adjusted so that Vout=0V.

3. At the desired temperature (e.g. 40° C.), the variable resistor VR is adjusted so that Vout=0V.

While the present invention has been described based on the embodiments and the Examples, the present invention can be implemented in various modified forms. The various modified implementations also fall within the scope of the present invention.

### INDUSTRIAL APPLICABILITY

When a signal level or the like (including AC amplitude or DC voltage) has a temperature coefficient, the temperature coefficient can be compensated by using the amplifier circuit with a variable temperature coefficient of a gain according to the present invention.

When a targeted circuit includes a parameter having a temperature coefficient and the parameter can be compensated with a direct voltage having a temperature coefficient, the parameter having the temperature coefficient of the targeted circuit can be compensated using following circuits according to the present invention. A direct voltage with a variable temperature coefficient obtained by connecting a direct voltage source to an input of an amplifier circuit with a variable temperature coefficient of a gain is used. A direct voltage with a variable temperature coefficient, which becomes a reference potential at a reference temperature, obtained by using a modified circuit of an amplifier circuit with a variable temperature coefficient of a gain and connecting a direct voltage source to an input is used. As a more specific application example, a temperature characteristic of an oscillation frequency of an AT-cut crystal oscillator can be approximately linearly approximated and compensated within a temperature range actually used by means of a direct voltage having a temperature coefficient by any of the circuits described above.

When the temperature characteristic of the targeted circuit is a U-shape or V-shape, the temperature characteristic of the targeted circuit can be compensated using the circuit configured to perform inverted V-shaped compensation according to the present invention. In addition, when the temperature characteristic of the targeted circuit is an inverted U-shape or inverted V-shape, the temperature characteristic of the targeted circuit can be compensated using the circuit configured to perform V-shape compensation according to the present invention. As a more specific application example, the temperature characteristic of an oscillation frequency can be compensated using a circuit configured to perform inverted V-shaped compensation on the inverted U-shaped temperature characteristic of the oscillation frequency of a crystal oscillator (excluding an AT-cut) according to the present invention.

### EXPLANATION OF REFERENCES

100, 100′, 200, 200′, 300, 400: temperature coefficient circuit; 501, 502: another amplifier circuit; 503: temperature coefficient inverting circuit; 504: inverting amplifier circuit; 601: 1/50 attenuator; 602: switchable attenuator; 603: IV amplifier; 604: voltage adjusting circuit; Ub, Ub′, Ub″: buffer amplifier; VR: variable resistor; VR_{A}: first variable resistor; VR_{B}: second variable resistor; Vo: output; Vo1: first signal; Vo2: second signal; Vo3: third signal; V_{DC}: direct voltage source; Ic: constant current source; U_{A}: first operational amplifier; U_{B}: second operational amplifier; D_{A}: first diode; D_{B}: second diode.

What is claimed is:

1. An amplifier circuit with a variable temperature coefficient of a gain, wherein:
a variable resistor is connected between a first signal and a second signal having temperature coefficients of an amplification factor different from each other,
a variable output of the variable resistor is connected to an input of a buffer amplifier, and
an output of the buffer amplifier is used as an output, wherein
the first signal is an output of a first temperature coefficient circuit, and
the second signal is
an output of another amplifier circuit,
an output of a second temperature coefficient circuit,
an output of a temperature coefficient inverting circuit configured to use the first signal as an input, or
an input of the amplifier circuit with a variable temperature coefficient of a gain.

2. The amplifier circuit with the variable temperature coefficient of the gain according to claim 1, wherein when an impedance of a load connected to an output of the amplifier circuit with the variable temperature coefficient of a gain is higher than an impedance of the variable resistor seen from the variable output, the buffer amplifier is omitted.

3. The amplifier circuit with the variable temperature coefficient of the gain according to claim 1, wherein a voltage-current converting circuit is used as the buffer amplifier and a current output is used.

4. The amplifier circuit with the variable temperature coefficient of the gain according to claim 1, wherein
the first temperature coefficient circuit and the second temperature coefficient circuit are each
an inverting amplifier circuit in which a temperature coefficient resistor is used for one or more of a feedback resistor or a gain resistor,
a non-inverting amplifier circuit in which a temperature coefficient resistor is used for one or more of a feedback resistor or a gain resistor,
a non-inverting amplifier circuit in which a first attenuator is provided to an input and a temperature coefficient resistor is used for one or more of a resistor configuring the first attenuator, a feedback resistor or a gain resistor,
a non-inverting amplifier circuit in which a second attenuator is provided to an output and a temperature coefficient resistor is used for one or more of a resistor configuring the second attenuator, a feedback resistor or a gain resistor, or
a non-inverting amplifier circuit in which a third attenuator is provided to an output, a temperature coefficient resistor is used for one or more of a resistor configuring the third attenuator, a feedback resistor or a gain resistor, and a buffer amplifier is provided to an output of the third attenuator.

5. The amplifier circuit with the variable temperature coefficient of the gain according to claim 1, wherein
in the temperature coefficient inverting circuit,
a non-inverting input of an operational amplifier configuring the temperature coefficient inverting circuit is connected to an input of the amplifier circuit with a variable temperature coefficient of a gain, or an output of another amplifier circuit,
an inverting input of the operational amplifier configuring the temperature coefficient inverting circuit is connected to one end of a feedback resistor and one end of a gain resistor,
an output of the operational amplifier configuring the temperature coefficient inverting circuit is connected to an opposite end of the feedback resistor,
an output of the first temperature coefficient circuit is connected to an opposite end of the gain resistor, and
the feedback resistor and the gain resistor have substantially same resistance values.

6. The amplifier circuit with the variable temperature coefficient of the gain according to claim 1, wherein a temperature coefficient of another amplifier circuit having a temperature coefficient in an output is compensated.

7. The amplifier circuit with the variable temperature coefficient of the gain according to claim 1, wherein the temperature coefficients of an amplification factor are adjusted to temperature coefficients proportional to an absolute temperature.

8. The amplifier circuit with the variable temperature coefficient of the gain according to claim 1, wherein
a direct voltage source having a temperature coefficient in an output voltage is connected to the input, and
the temperature coefficient of the direct voltage source is compensated and output.

9. The amplifier circuit with the variable temperature coefficient of the gain according to claim 1, wherein
a direct voltage source having a temperature coefficient in an output voltage is connected to the input,
a first variable resistor and a second variable resistor are provided as the variable resistor,
the buffer amplifier is not provided,
a variable output of the first variable resistor is connected to a non-inverting input of a first operational amplifier,
a variable output of the second variable resistor is connected to a non-inverting input of a second operational amplifier,
an output of the first operational amplifier is connected to an inverting input of the first operational amplifier via a first diode,
an output of the second operational amplifier is connected to an inverting input of the second operational amplifier via a second diode,
the inverting input of the first operational amplifier and the inverting input of the second operational amplifier are connected in common,
a constant current source or a resistor is provided between the common connection and a voltage source, and
the common connection is used as an output,
so that the temperature coefficient of the direct voltage source is independently compensated and output at temperatures higher and lower than a reference temperature.

10. The amplifier circuit with the variable temperature coefficient of the gain according to claim 1, wherein the whole or a part of the amplifier circuit with the variable temperature coefficient of a gain is configured as a circuit module.

11. The amplifier circuit with the variable temperature coefficient of the gain according to claim 1, wherein a range of the temperature coefficient is switchable.

12. The amplifier circuit with the variable temperature coefficient of the gain according to claim 2, wherein
the first temperature coefficient circuit and the second temperature coefficient circuit are each
an inverting amplifier circuit in which a temperature coefficient resistor is used for one or more of a feedback resistor or a gain resistor,
a non-inverting amplifier circuit in which a temperature coefficient resistor is used for one or more of a feedback resistor or a gain resistor,
a non-inverting amplifier circuit in which a first attenuator is provided to an input and a temperature coefficient resistor is used for one or more of a resistor configuring the first attenuator, a feedback resistor or a gain resistor,
a non-inverting amplifier circuit in which a second attenuator is provided to an output and a temperature coefficient resistor is used for one or more of a resistor configuring the second attenuator, a feedback resistor or a gain resistor, or
a non-inverting amplifier circuit in which a third attenuator is provided to an output, a temperature coefficient resistor is used for one or more of a resistor configuring the third attenuator, a feedback resistor or a gain resistor, and a buffer amplifier is provided to an output of the third attenuator.

13. The amplifier circuit with the variable temperature coefficient of the gain according to claim 3, wherein
the first temperature coefficient circuit and the second temperature coefficient circuit are each
an inverting amplifier circuit in which a temperature coefficient resistor is used for one or more of a feedback resistor or a gain resistor,
a non-inverting amplifier circuit in which a temperature coefficient resistor is used for one or more of a feedback resistor or a gain resistor,
a non-inverting amplifier circuit in which a first attenuator is provided to an input and a temperature coefficient resistor is used for one or more of a resistor configuring the first attenuator, a feedback resistor or a gain resistor,
a non-inverting amplifier circuit in which a second attenuator is provided to an output and a temperature coefficient resistor is used for one or more of a resistor configuring the second attenuator, a feedback resistor or a gain resistor, or
a non-inverting amplifier circuit in which a third attenuator is provided to an output, a temperature coefficient resistor is used for one or more of a resistor configuring the third attenuator, a feedback resistor or a gain resistor, and a buffer amplifier is provided to an output of the third attenuator.

14. The amplifier circuit with the variable temperature coefficient of the gain according to claim 2, wherein
in the temperature coefficient inverting circuit,
a non-inverting input of an operational amplifier configuring the temperature coefficient inverting circuit is connected to an input of the amplifier circuit with a variable temperature coefficient of a gain, or an output of another amplifier circuit,
an inverting input of the operational amplifier configuring the temperature coefficient inverting circuit is connected to one end of a feedback resistor and one end of a gain resistor,
an output of the operational amplifier configuring the temperature coefficient inverting circuit is connected to an opposite end of the feedback resistor,
an output of the first temperature coefficient circuit is connected to an opposite end of the gain resistor, and
the feedback resistor and the gain resistor have substantially same resistance values.

15. The amplifier circuit with the variable temperature coefficient of the gain according to claim 3, wherein
in the temperature coefficient inverting circuit,
a non-inverting input of an operational amplifier configuring the temperature coefficient inverting circuit is connected to an input of the amplifier circuit with a variable temperature coefficient of a gain, or an output of another amplifier circuit,
an inverting input of the operational amplifier configuring the temperature coefficient inverting circuit is connected to one end of a feedback resistor and one end of a gain resistor,
an output of the operational amplifier configuring the temperature coefficient inverting circuit is connected to an opposite end of the feedback resistor,
an output of the first temperature coefficient circuit is connected to an opposite end of the gain resistor, and
the feedback resistor and the gain resistor have substantially same resistance values.

16. The amplifier circuit with the variable temperature coefficient of the gain according to claim 2, wherein
a temperature coefficient of another amplifier circuit having a temperature coefficient in an output is compensated.

17. The amplifier circuit with the variable temperature coefficient of the gain according to claim 3, wherein
a temperature coefficient of another amplifier circuit having a temperature coefficient in an output is compensated.

18. A circuit for generating a voltage with a variable temperature coefficient, which becomes a reference potential at a reference temperature, by:
using the amplifier circuit with the variable temperature coefficient of the gain according to claim 1 in which
the second signal is set to an output of the temperature coefficient inverting circuit,
a third signal is set to a signal in which a polarity of the output of the temperature coefficient inverting circuit is inverted, or a reference potential, and
the variable resistor is connected between the second signal and the third signal, which have temperature coefficients of an amplification factor different from each other, and
applying a direct voltage to the input of the amplifier circuit with a variable temperature coefficient of a gain.

19. A direct voltage generating circuit using the amplifier circuit with the variable temperature coefficient of the gain according to claim 7, the direct voltage generating circuit being configured to output a voltage proportional to an absolute temperature by connecting a direct voltage source to an input.

20. A circuit using the circuit for generating the voltage with the variable temperature coefficient, which becomes the reference potential at the reference temperature, according to claim 18, the circuit being configured:
to apply an output of the circuit for generating a voltage with a variable temperature coefficient to an input of another amplifier circuit, and
to compensate for a temperature drift of the other amplifier circuit.
